(19) United States
(12) Patent Application Publication
(10) Pub. No.: US 2026/0253619 A1
(43) Pub. Date: Aug. 27, 2026

(54) THREE-DIMENSIONAL MEMORY DEVICE CONTAINING LATERALLY SPLIT STAIRCASE REGIONS

(71) Applicant: Sandisk Technologies, Inc., Milpitas, CA (US)

(72) Inventor: Hirofumi TOKITA, Yokkaichi (JP)

(21) Appl. No.: 19/064,385

(22) Filed: Feb. 26, 2025

(51) Int. Cl. G11C 5/06; G11C 16/04; H10B 41/10; H10B 41/27; H10B 41/35; H10B 43/10; H10B 43/27; H10B 43/35

(52) U.S. Cl. CPC G11C 5/06; G11C 16/0483; H10B 41/10; H10B 41/27; H10B 41/35; H10B 43/10; H10B 43/27; H10B 43/35

(57) ABSTRACT

A device structure includes a multi-tier structure containing a first-tier structure, a second-tier structure, and a third-tier structure. Each tier structure includes a respective alternating stack of insulating layers and electrically conductive layers embedding a respective set of retro-stepped dielectric material portions. At least one set of retro-stepped dielectric material portion includes three or more retro-stepped dielectric material portions that are laterally spaced apart from each other.

### FIELD

The present disclosure relates generally to the field of semiconductor devices, and particularly to a three-dimensional memory device containing laterally split staircase regions.

### BACKGROUND

A three-dimensional memory device including three-dimensional vertical NAND strings having one bit per cell is disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a device structure comprises a multi-tier structure comprising a first-tier structure including a first-tier alternating stack of first-tier insulating layers and first-tier electrically conductive layers, a second-tier structure overlying the first-tier structure and including a second-tier alternating stack of second-tier insulating layers and second-tier electrically conductive layers, and a third-tier structure overlying the second-tier structure and including a third-tier alternating stack of third-tier insulating layers and third-tier electrically conductive layers; a first memory array region comprising a plurality of first memory opening fill structures vertically extending through the multi-tier structure; a second memory array region comprising a plurality of second memory opening fill structures vertically extending through the multi-tier structure, the second memory array region is laterally offset from the first memory array region along a first horizontal direction by a contact region of the multi-tier structure; and a set of retro-stepped dielectric material portions embedded in the contact region. The first-tier alternating stack embeds a first subset of the respective set of retro-stepped dielectric material portions, the second-tier alternating stack embeds a second subset of the respective set of retro-stepped dielectric material portions, and the third-tier alternating stack embeds a third subset of the respective set of retro-stepped dielectric material portions. At least one subset of the first subset, the second subset, or the third subset comprises three or more retro-stepped dielectric material portions that are laterally spaced apart from each other along the first horizontal direction.

According to another aspect of the present disclosure, a device structure comprises a plurality of multi-tier structures that are laterally spaced apart from each other along a second horizontal direction by a plurality of lateral isolation trenches that laterally extend along a first horizontal direction. Each multi-tier structure within the plurality of multi-tier structures comprises a first-tier structure including a first-tier alternating stack of first-tier insulating layers and first-tier electrically conductive layers, a second-tier structure overlying the first-tier structure and including a second-tier alternating stack of second-tier insulating layers and second-tier electrically conductive layers, and a third-tier structure overlying the second-tier structure and including a third-tier alternating stack of third-tier insulating layers and third-tier electrically conductive layers. Each of the multi-tier structures embeds a respective set of retro-stepped dielectric material portions, wherein the first-tier alternating stack of each multi-tier structure embeds a first subset of the respective set of retro-stepped dielectric material portions, the second-tier alternating stack of each multi-tier structure embeds a second subset of the respective set of retro-stepped dielectric material portions, and the third-tier alternating stack of each multi-tier structure embeds a third subset of the respective set of retro-stepped dielectric material portions. Within each multi-tier structure, the first subset has a first lateral extent along the first horizontal direction, the second subset has a second lateral along the first horizontal direction, and the third subset has a third lateral extent along the first horizontal direction. The plurality of multi-tier structures comprises a first multi-tier structure and a second multi-tier structure. The second lateral extent of the first multi-tier structure is less than the first lateral extent of the first multi-tier structure. The second lateral extent of the second multi-tier structure is greater than the first lateral extent of the second multi-tier structure.

### BRIEF DESCRIPTION OF THE DRAWINGS

Within each of FIGS. 2A-2E, 5A-7E, 9A-10E, and 14A-18E, each figure is labeled with a combination of a figure numeral and a alphabetical suffix. Each set of figures with the same figure numeral corresponds to views for a first exemplary structure at a same processing step. Each figure with the alphabetical suffix “A” is a vertical cross-sectional view along a vertical plane A-A′ in the figure with the same figure numeral and the alphabetical suffix “E.”. Each figure with the alphabetical suffix “B” is a vertical cross-sectional view along a vertical plane B-B′ in the figure with the same figure numeral and the alphabetical suffix “E.” Each figure with the alphabetical suffix “C” is a vertical cross-sectional view along a vertical plane C-C′ in the figure with the same figure numeral and the alphabetical suffix “E.” Each figure with the alphabetical suffix “D” is a vertical cross-sectional view along a vertical plane D-D′ in the figure with the same figure numeral and the alphabetical suffix “E.” Each figure with the alphabetical suffix “E” is a top-down view for the first exemplary structure shown in figures with the same figure numeral and alphabetical suffices “A,” “B,” “C,” and “D.”

FIG. 1 is a vertical cross-sectional view of a first exemplary structure for forming a semiconductor die after formation of a vertically alternating sequence of first-tier continuous insulating layers and first-tier continuous sacrificial material layers according to an embodiment of the present disclosure.

FIGS. 2A-2E are various views of the first exemplary structure after formation of first-tier stepped cavities, local thickening of physically exposed first-tier sacrificial material layers, and formation of first-tier retro-stepped dielectric material portions according to an embodiment of the present disclosure.

FIGS. 3A-3C are sequential vertical cross-sectional views of a region of the first exemplary structure during thickening of physically-exposed portions of the first-tier sacrificial material layers according to an embodiment of the present disclosure.

FIGS. 4A-4E are sequential vertical cross-sectional views of a region of the first exemplary structure during a sequence of processing steps that may be employed to locally thicken the physically-exposed portions of the first-tier sacrificial material layers according to an embodiment of the present disclosure.

FIGS. 5A-5E are various views of the first exemplary structure after formation of various first-tier openings and various first-tier sacrificial opening fill structures according to an embodiment of the present disclosure.

FIGS. 6A-6E are various views of the first exemplary structure after formation of a vertically alternating sequence of second-tier continuous insulating layers and second-tier continuous sacrificial material layers, second-tier retro-stepped dielectric material portions, and various second-tier openings and various second-tier sacrificial opening fill structures according to an embodiment of the present disclosure.

FIGS. 7A-7E are various views of the first exemplary structure after formation of a vertically alternating sequence of third-tier continuous insulating layers and third-tier continuous sacrificial material layers, third-tier retro-stepped dielectric material portions, and various third-tier openings and various third-tier sacrificial opening fill structures according to an embodiment of the present disclosure.

FIGS. 8A-8G illustrate sequential vertical cross-sectional views of a memory opening during formation of a memory opening fill structure according to an embodiment of the present disclosure.

FIGS. 9A-9E are various views of the first exemplary structure after formation of memory opening fill structures according to an embodiment of the present disclosure.

FIGS. 10A-10E are various views of the first exemplary structure after formation of a contact-level dielectric layer and connection cavities according to an embodiment of the present disclosure.

FIG. 11 is a vertical cross-sectional view of the first exemplary structure after formation of contact via cavities according to an embodiment of the present disclosure.

FIG. 12 is a vertical cross-sectional view of the first exemplary structure after formation of annular lateral recesses around the contact via cavities according to an embodiment of the present disclosure.

FIG. 13 is a vertical cross-sectional view of the first exemplary structure after formation of annular dielectric spacers in a subset of the annular lateral recesses according to an embodiment of the present disclosure.

FIGS. 14A-14E are various views of the first exemplary structure after formation of sacrificial through-via structures according to an embodiment of the present disclosure.

FIGS. 15A-15E are various views of the first exemplary structure after formation of lateral isolation trenches according to an embodiment of the present disclosure.

FIGS. 16A-16E are various views of the first exemplary structure after replacement of the sacrificial material layers with electrically conductive layers according to an embodiment of the present disclosure.

FIGS. 17A-17E are various views of the first exemplary structure after formation of lateral isolation trench fill structures and removal of the sacrificial through-via structures according to an embodiment of the present disclosure.

FIGS. 18A-18E are various views of the first exemplary structure after formation of through-via contact structures according to an embodiment of the present disclosure.

FIG. 19A is a vertical cross-sectional view of the first exemplary structure after formation of drain contact via structures according to an embodiment of the present disclosure.

FIG. 19B is a top-down view of the first exemplary structure of FIG. 19A. The vertical plane A-A′ is the cut plane of the vertical cross-sectional view of FIG. 19A.

FIG. 20 is a vertical cross-sectional view of a second exemplary structure.

FIG. 21 is a vertical cross-sectional view of a third exemplary structure.

FIG. 22 is a vertical cross-sectional view of a fourth exemplary structure.

FIG. 23 is a vertical cross-sectional view of a fifth exemplary structure.

FIG. 24 is a vertical cross-sectional view of a sixth exemplary structure.

FIG. 25 is a vertical cross-sectional view of a seventh exemplary structure.

FIG. 26 is a vertical cross-sectional view of an eighth exemplary structure.

FIG. 27A is a first vertical cross-sectional view of a ninth exemplary structure. FIG. 27B is a second vertical cross-sectional view of the ninth exemplary structure. FIG. 27C is a third vertical cross-sectional view of the ninth exemplary structure. FIG. 27D is a top-down view of the ninth exemplary structure. The vertical planes A-A′, B-B, and C-C′ in FIG. 27D are cut planes of the views of FIG. 27A, FIG. 27B, and 27C, respectively.

FIG. 28A is a first vertical cross-sectional view of a tenth exemplary structure. FIG. 28B is a second vertical cross-sectional view of the tenth exemplary structure. FIG. 28C is a third vertical cross-sectional view of the tenth exemplary structure. FIG. 28D is a top-down view of the tenth exemplary structure. The vertical planes A-A′, B-B, and C-C′ in FIG. 28D are cut planes of the views of FIG. 28A, FIG. 28B, and 28C, respectively.

### DETAILED DESCRIPTION

As discussed above, embodiments of the present disclosure are directed to a three-dimensional memory devices containing laterally split staircase regions and methods for forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements. The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a “first-tier level” refers to the level that is most proximal to a growth substrate, a “second-tier level” refers to the level that is most proximal to the growth substrate of the levels that overlie the first-tier level, and a “third-tier level” refers to the level that is most proximal to the growth substrate of the levels that overlie the second-tier level, etc. A “first-tier” element refers to an element that is located within the first-tier level, a “second-tier” element refers to an element that is located within the second-tier level, a “third-tier” element refers to an element that is located within the second-tier level, etc. As used herein, a “memory level” or a “memory array level” refers to the level corresponding to a general region between a first horizontal plane (i.e., a plane parallel to the top surface of the growth substrate) including topmost surfaces of an array of memory elements and a second horizontal plane including bottommost surfaces of the array of memory elements. As used herein, a “through-stack” element refers to an element that vertically extends through a memory level.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and May optionally include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

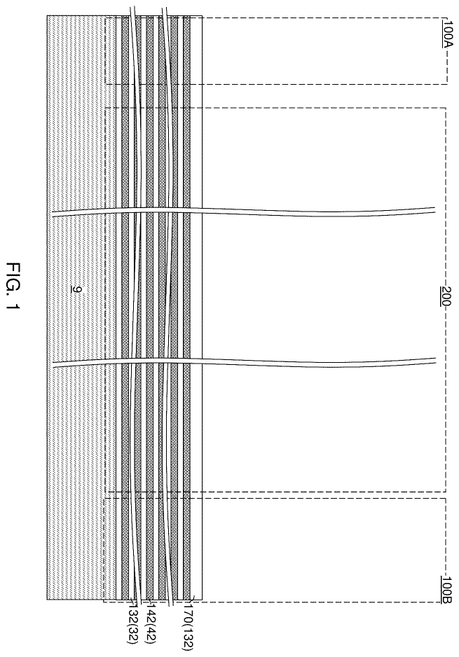

Referring to FIG. 1, a first exemplary structure according to an embodiment of the present disclosure is illustrated, which can be employed to form a two-dimensional array of memory dies formed on a substrate 9. The substrate 9 may be a commercially available wafer such as a silicon wafer. Alternatively, the substrate 9 may comprise another suitable material.

A first vertically alternating sequence of first-tier insulating layers 132 and first-tier sacrificial material layers 142 can be formed over a substrate 9. As used herein, a vertically alternating sequence refers to a sequence of multiple instances of a first element and multiple instances of a second element that is arranged such that an instance of a second element is located between each vertically neighboring pair of instances of the first element, and an instance of a first element is located between each vertically neighboring pair of instances of the second element. The first vertically alternating sequence of first-tier insulating layers 132 and first-tier sacrificial material layers 142 is also referred to as a first-tier alternating stack (132, 142). Generally, the first-tier insulating layers 132 are a first subset of insulating layers 32 to be formed in the first exemplary structure, and the first-tier sacrificial material layers 142 are a first subset of sacrificial material layers 42 to be formed in the first exemplary structure. As such, the first-tier alternating stack (132, 142) is one of alternating stacks (32, 42) that are formed in the first exemplary structure.

The first-tier insulating layers 132 can be composed of the first material, and the first-tier sacrificial material layers 142 can be composed of the second material, which is different from the first material. Each of the first-tier insulating layers 132 is an insulating layer that continuously extends over the entire area of the substrate 9, and may have a uniform thickness throughout. Each of the first-tier sacrificial material layers 142 includes a sacrificial material (which may comprise a dielectric material), and continuously extends over the entire area of the substrate 9, and may have a uniform thickness throughout. Insulating materials that may be used for the first-tier insulating layers 132 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the first-tier insulating layers 132 may be silicon oxide. The topmost one of the first-tier insulating layers 132 is herein referred as a first-tier insulating cap layer 170.

The second material of the first-tier sacrificial material layers 142 is a dielectric material, which is a sacrificial material that may be removed selectively to the first material of the first-tier insulating layers 132. As used herein, removal of a first material is “selective to” a second material if the removal process removes the first material at a removal rate that is at least twice the removal rate for the second material. The ratio of the rate of removal of the first material to the rate of removal of the second material is herein referred to as a “selectivity” of the removal process for the first material with respect to the second material.

The thickness of each first-tier insulating layer 132 may be in a range from 12 nm to 50 nm, such as from 15 nm to 30 nm, although lesser and greater thicknesses may also be employed. The thickness of each first-tier sacrificial material layer 142 may be in a range from 15 nm to 50 nm, such as from 20 nm to 30 nm, although lesser and greater thicknesses may also be employed. The second material of the first-tier sacrificial material layers 142 may be subsequently replaced with electrically conductive electrodes which may function, for example, as control gate electrodes of a vertical NAND device. In one embodiment, the first-tier sacrificial material layers 142 may comprise silicon nitride.

Generally, a vertically alternating sequence of unit layer stacks over a substrate. Each of the unit layer stacks comprises a first-tier insulating layer (such as a first-tier insulating layer 132) and a first spacer material layer (such as a first-tier sacrificial material layer 142). Generally, the first spacer material layers are formed as, or are subsequently replaced with, first-tier electrically conductive layers. While the present disclosure is described employing an embodiment in which the first spacer material layers are formed as first-tier sacrificial material layers 142 that are subsequently replaced with first-tier electrically conductive layers, embodiments are expressly contemplated herein in which the first spacer material layers are formed as first-tier electrically conductive layers. In such embodiments, steps for replacing the material of the first spacer material layers with an electrically conductive material can be omitted. The first exemplary structure comprises a pair of memory array regions (100A, 100B) and a contact region 200 located between the pair of memory array regions (100A, 100B). The pair of memory regions (100A, 100B) may comprise a first memory array region 100A and a second memory array region 100B.

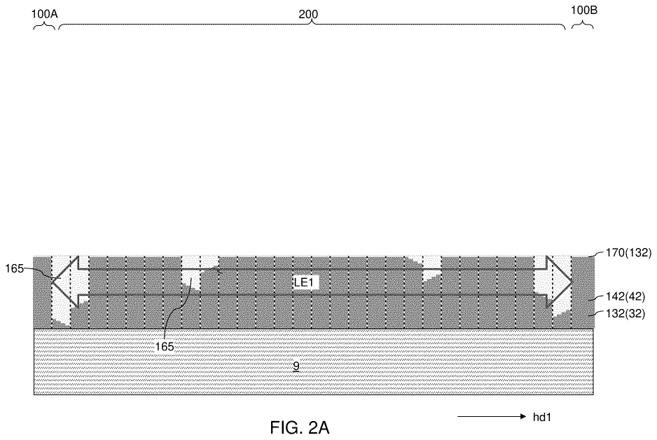

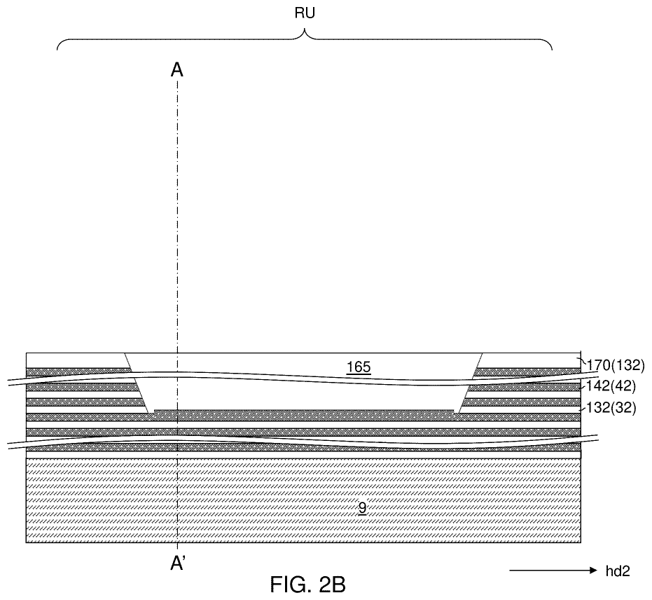

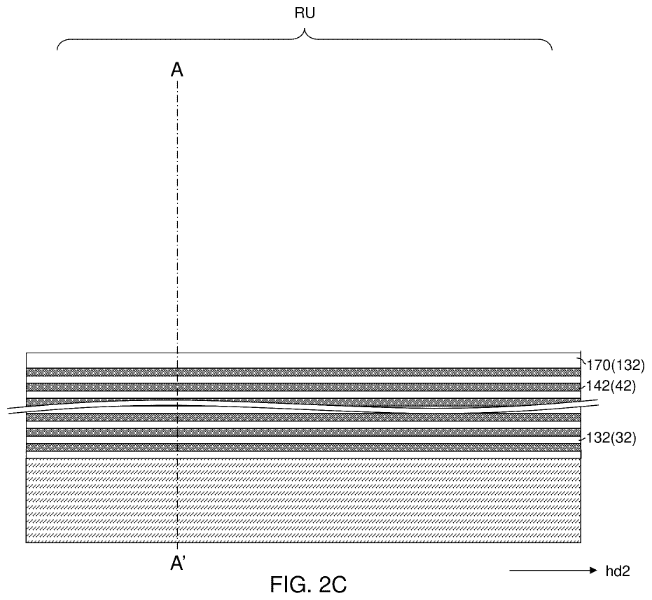

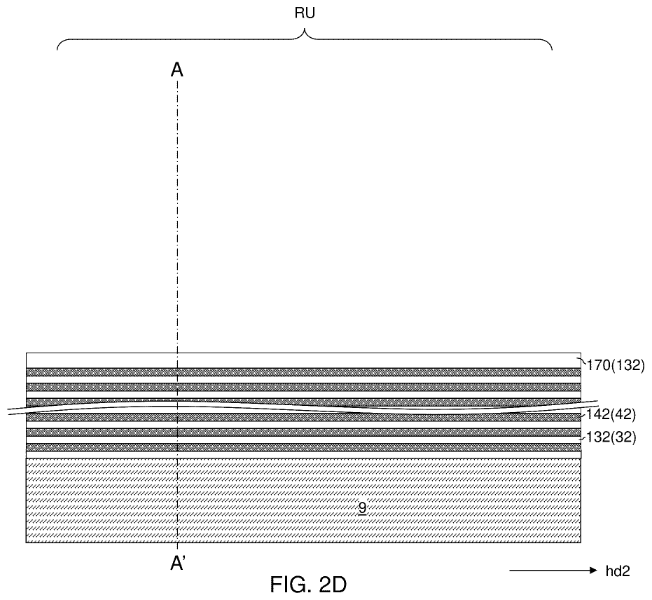

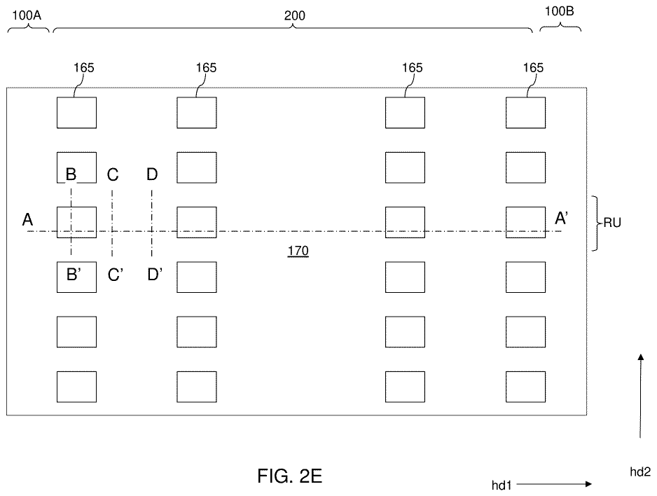

Referring to FIGS. 2A-2E, first-tier stepped cavities can be formed through the first-tier alternating stack (132, 142). The first-tier stepped cavities can be formed in a periodic pattern within the area of the contact region 200. For example, the first memory array region 100A and the second memory array region 100B may be laterally spaced apart from each other along a first horizontal direction (e.g., word line direction) hd1. The contact region 200 may be located between the first memory array region 100A and the second memory array region 100B. The first-tier stepped cavities may be laterally spaced apart along a second horizontal direction (e.g., bit line direction) hd2 that is perpendicular to the first horizontal direction hd1. In one embodiment, the first-tier stepped cavities may be formed as a periodic one-dimensional array of first-tier stepped cavities arranged along the second horizontal direction hd2. In this case, the pattern of the first-tier stepped cavities may be a periodic repetition of a unit pattern located within a repetition unit RU.

In the illustrated example, each repetition unit RU laterally extends along the first horizontal direction hd1 through the entirety of the first memory array region 100A (of which only an edge portion is illustrated), the entirety of the second memory array region 100B (of which only an edge portion is illustrated), and the contact region 200. The width of the repetition unit RU may be the same as the periodicity of the periodic one-dimensional array of first-tier stepped cavities. Generally, each repetition unit RU may be defined as a rectangular area having a lengthwise edge that is parallel to the first horizontal direction hd1 at any location. In the illustrated example, each repetition unit RU is defined to have lengthwise edges that coincide with two mirror symmetry vertical planes for a neighboring pair of first-tier stepped cavities along the first horizontal direction hd1. In this case, each of the two mirror symmetry vertical planes extends through a respective one of the first-tier stepped cavities. The pattern in the repetition unit RU may be repeated along the second horizontal direction hd2.

In one embodiment, first-tier stepped surfaces can be formed within the first-tier stepped cavities of the contact region 200 by patterning the first vertically alternating sequence (132, 142). The first-tier stepped surfaces that form the bottom of the first-tier stepped cavities are referred to as a first-tier staircase region which is located in the contact region 200 between the memory array regions (100A, 100B). For example, a combination of a sacrificial hard mask layer and a trimming mask layer may be employed to form the first stepped surfaces. Each first-tier stepped cavity comprises a respective contiguous set of stepped surfaces of the first vertically alternating sequence (132, 142). The stepped surfaces comprise horizontal surface segments separated by vertical surface segments. The lateral extents of the first-tier sacrificial material layers 142 vary with a vertical distance from the substrate 9 in each first-tier stepped cavity. Each of the first-tier sacrificial material layers 142 has a respective physically exposed horizontal top surface segment within each first-tier stepped cavity. The sidewalls of each first-tier staircase region may be tapered. The area in which the physically exposed horizontal surface segments of the first-tier stepped surfaces of a first-tier stepped cavity is located within a plan view is herein referred to as a first-tier stepped surface area.

In one embodiment, a plurality of first-tier stepped cavities laterally spaced from each other along the first horizontal direction hd1 may be formed in each repetition unit RU. In one embodiment, three or more first-tier stepped cavities laterally spaced from each other along the first horizontal direction hd1 may be formed in each repetition unit RU. In the illustrated configuration of the first exemplary structure, four first-tier stepped cavities are formed within the area of each repetition unit RU in the contact region 200.

In one embodiment, each first-tier stepped cavity may comprise a respective set of at least one ascending staircase surface containing first horizontal surface segments of which vertical distances from a top surface of the substrate 9 increase stepwise along the first horizontal direction hd1, and at least one descending staircase surface containing second horizontal surface segments of which vertical distances from the top surface of the substrate decrease stepwise along the first horizontal direction hd1. As used herein, an ascending staircase surface refers to a contiguous set of horizontal surface segments and vertical surface segments that are adjoined to each other such that the height of the horizontal surface segments increase stepwise along a horizontal propagation of the contiguous set of horizontal surface segments and vertical surface segments (which is parallel to the spacing between the vertical surface segments). As used herein, a descending staircase surface refers to a contiguous set of horizontal surface segments and vertical surface segments that are adjoined to each other such that the height of the horizontal surface segments decrease stepwise along a horizontal propagation of the contiguous set of horizontal surface segments and vertical surface segments (which is parallel to the spacing between the vertical surface segments). An ascending staircase along a reference horizontal direction is a descending staircase along a direction that is the opposite direction of the reference horizontal direction, and vice versa.

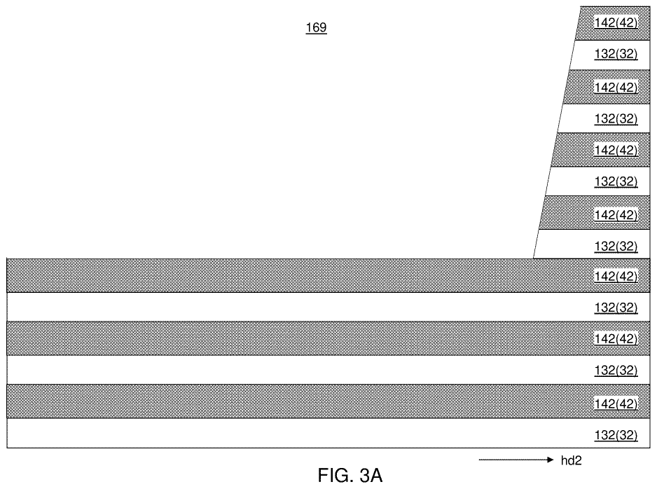

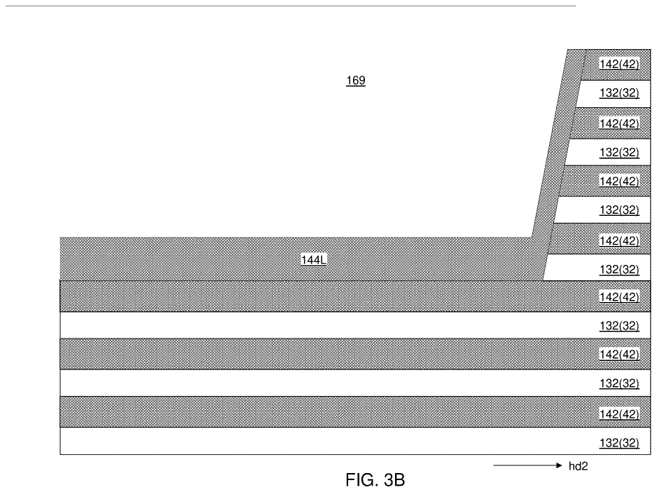

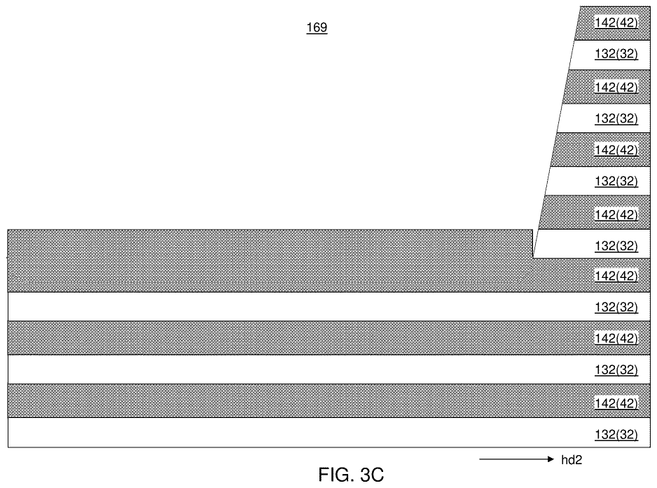

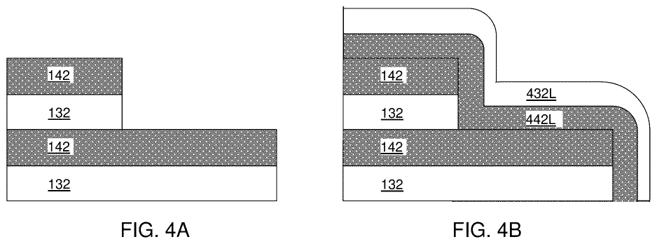

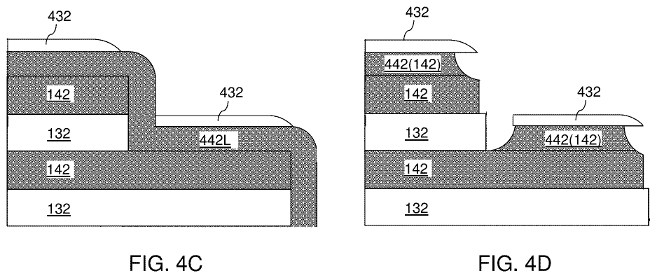

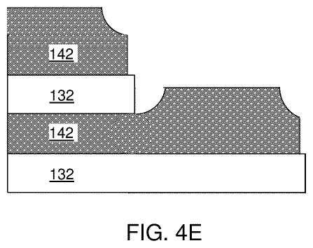

Physically exposed horizontally-extending portions of the first-tier sacrificial material layers 142 may be locally thickened by performing suitable processing steps. Various processing schemes may be performed to locally thicken the physically exposed horizontally-extending portions of the of the first-tier sacrificial material layers 142. FIGS. 3A-3C and FIGS. 4A-4E illustrates two exemplary sequence of processing steps that may be employed to locally thicken the first-tier sacrificial material layers 142.

FIGS. 3A-3C are sequential vertical cross-sectional views of a region of the first exemplary structure during thickening of physically-exposed portions of the first-tier sacrificial material layers according to an embodiment of the present disclosure.

Referring to FIG. 3A, an anisotropic material deposition process can be performed to anisotropically deposit a same material as the material of the first-tier sacrificial material layers 142 to form a non-conformal sacrificial material layer 144L. In one embodiment, the first-tier sacrificial material layers 142 comprise silicon nitride, and the anisotropic material deposition process may deposit a silicon nitride material anisotropically. The non-conformal sacrificial material layer 144L is deposited by a non-conformal deposition process such as a plasma-enhanced chemical vapor deposition (PECVD) process. Preferably, the deposition of the sacrificial material of the non-conformal sacrificial material layer 144L is highly anisotropic such that the thickness of each horizontally-extending portion of the non-conformal sacrificial material layer 144L is greater than (e.g., at least twice) the thickness of non-horizontally-extending portions of the non-conformal sacrificial material layer 144L. In one embodiment the thickness of the horizontally-extending portions of the non-conformal sacrificial material layer 144L may be in a range from 50% to 300% of the thickness of each first-tier sacrificial material layer 142.

Referring to FIG. 3B, an isotropic etch process can be performed to isotropically recess the non-conformal sacrificial material layer 144L. The duration of the isotropic etch process can be selected such that the non-horizontally-extending portions of the non-conformal sacrificial material layer 144L are removed by the isotropic etch process. Remaining horizontally-extending portions of the non-conformal sacrificial material layer 144L overlying a top surface segment of a respective one of the first-tier sacrificial material layers 142 can be incorporated into the respective one of the first-tier sacrificial material layers 142.

Thus, physically-exposed portions of the sacrificial material layers 42 (such as the first-tier sacrificial material layers 142) in the staircase region can be thickened such that the thickened portions of the sacrificial material layers 142 has a thickness in a range from 125% to 250%, such as from 150% to 200%, of the unthickened portion of the first-tier sacrificial material layers 142 (which is the same as the original thickness of each first-tier sacrificial material layers 142). While an embodiment is described in which physically exposed portions of the first-tier sacrificial material layers 142 are locally thickened by anisotropic deposition and isotropic etch-back of a sacrificial material, the physically exposed portions of the first-tier sacrificial material layers 142 may be locally thickened by alternative methods that can selectively increase the thickness of physically exposed portions of the first-tier sacrificial material layers 142.

Referring to FIG. 3C, portions of the non-conformal sacrificial material layer 144L that are deposited outside the areas of the first-tier stepped cavities can be removed, for example, by covering the areas of the first-tier stepped cavities with patterned photoresist materials without covering sidewalls of the first-tier stepped cavities, and by performing an etch process that etches unmasked portions of the material of the non-conformal sacrificial material layer 144L. Physically exposed portions of the first-tier sacrificial material layers 142 may be locally thickened within the first-tier stepped cavities.

Local thickening of the physically exposed portions of the first-tier sacrificial material layers 142 may be performed employing alternative methods. FIGS. 4A-4E are sequential vertical cross-sectional views of a region of the first exemplary structure during a sequence of processing steps that may be employed to locally thicken the physically-exposed portions of the first-tier sacrificial material layers according to an embodiment of the present disclosure.

Referring to FIG. 4A, a region of the first-tier stepped surfaces in a first-tier stepped cavity after the processing steps of FIGS. 2A-2E is illustrated.

Referring to FIG. 4B, an additive sacrificial material layer 442L can be conformally deposited by a conformal deposition process such as a low pressure chemical vapor deposition process. The thickness of the additive sacrificial material layer 442L may be in a range from 40% to 300%, such as from 60% to 150%, of the thickness of each first-tier sacrificial material layer 142. The additive sacrificial material layer 442L may comprise the same material as the first-tier sacrificial material layers 142. For example, if the first-tier sacrificial material layers 142 comprise silicon nitride, the additive sacrificial material layer 442L may comprise silicon nitride.

Subsequently, a non-conformal cover material layer 432L may be anisotropically deposited. The anisotropic deposition of the non-conformal cover material layer 432L may be effected, for example, by plasma enhanced chemical vapor deposition. The non-conformal cover material layer 432L comprises a material that can function as an etch mask material for subsequently etching unmasked portions of the additive sacrificial material layer 442L. For example, the non-conformal cover material layer 432L may comprise silicon oxide. The vertical thickness of the horizontally-extending portions of the non-conformal cover material layer 432L is greater than the lateral thickness of the vertically-extending portions of the non-conformal cover material layer 432L. The difference between the vertical thickness of the horizontally-extending portions of the non-conformal cover material layer 432L and the lateral thickness of the vertically-extending portions of the non-conformal cover material layer 432L may be in a range from 1.3 to 3.0, such as from 1.5 to 2.0.

Referring to FIG. 4C, an isotropic etch process can be performed to isotropically etch the material of the non-conformal cover material layer 432L. The duration of the isotropic etch process is selected such that the etch distance of the isotropic etch process for the material of the non-conformal cover material layer 432L is greater than the lateral thickness of vertically-extending portions of the non-conformal cover material layer 432L, and is less than the vertical thickness of the horizontally-extending portions of the non-conformal cover material layer 432L. Thus, remaining portions of the non-conformal cover material layer 432L after the isotropic etch process comprise cover material plates 432 that are remaining portions of the non-conformal cover material layer 432L that overlie horizontally-extending portions of the additive sacrificial material layer 442L. The cover material plates 432 have a vertical thickness that is not greater than the difference between the vertical thickness of the horizontally-extending portions of the non-conformal cover material layer 432L and the lateral thickness of vertically-extending portions of the non-conformal cover material layer 432L, and may be in a range from 10 nm to 50 nm, although lesser and greater thicknesses may also be employed.

Referring to FIG. 4D, a selective isotropic etch process can be performed to isotropically etch unmasked portions of the additive sacrificial material layer 442L without etching the materials of cover material plates 432 or the first-tier insulating layers 132. The duration of the selective isotropic etch process may be selected such that the etch distance of the selective isotropic etch process for the material of the additive sacrificial material layer 442L is not less than the uniform thickness of the additive sacrificial material layer 442L. Thus, vertically-extending portions of the additive sacrificial material layer 442L are removed by the selective isotropic etch process, while remaining horizontally-extending portions of the additive sacrificial material layer 442L underlie a respective one of the cover material plates 432. The remaining horizontally-extending portions of the additive sacrificial material layer 442L comprise sacrificial material plates 442, which are incorporated into a respective one of the first-tier sacrificial material layers 142.

Referring to FIG. 4E, a selective etch process may be optionally performed to remove the cover material plates 432 without removing the materials of the sacrificial material plates 442 or the first-tier sacrificial material layers 142. The material of sacrificial material plates 442 may be the same as the material of the first-tier sacrificial material layers 142. Thus, the first-tier sacrificial material layers 142 incorporate the sacrificial material plates 442, and are locally thickened in the regions of the first stepped surfaces.

Referring back to FIGS. 2A-2E, a first dielectric fill material (such as undoped silicate glass (i.e., silicon oxide) or a doped silicate glass) can be deposited in each first-tier stepped cavity. The first dielectric fill material can be planarized to remove excess portions of the first dielectric fill material from above the horizontal plane including the topmost surface of the first vertically alternating sequence (132, 142). Each remaining portion of the first dielectric fill material that fills a respective first-tier stepped cavity constitutes a first-tier retro-stepped dielectric material portion 165. Generally, a plurality of first-tier retro-stepped dielectric material portions 165 can be formed in the contact region 200 within each repetition unit RU between the first memory array region 100A and the second memory array region 100B that are laterally spaced apart along the first horizontal direction hd1. The planar top surface of each first-tier retro-stepped dielectric material portion 165 can be located within a horizontal plane including the top surface of the first-tier insulating cap layer 170.

Each repetition unit RU comprises a respective set of first-tier retro-stepped dielectric material portions 165. In one embodiment, each first-tier retro-stepped dielectric material portion 165 comprises at least one ascending staircase bottom surface containing first horizontal surface segments of which vertical distances from a top surface of the growth substrate 9 increase stepwise along the first horizontal direction hd1, and at least one descending staircase bottom surface containing second horizontal surface segments of which vertical distances from the top surface of the growth substrate 9 decrease stepwise along the first horizontal direction hd1.

Each repletion unit RU may comprise a plurality of first-tier retro-stepped dielectric material portions 165, which may comprise three or more first-tier retro-stepped dielectric material portions 165. In the illustrated example, each repetition unit RU comprises four retro-stepped dielectric material portions 165. Each first-tier retro-stepped dielectric material portion 165 has a plurality of sidewalls that are perpendicular to the first horizontal direction. As used herein, within each repetition unit RU, the maximum lateral spacing along the first horizontal direction hd1 among sidewalls of the first-tier retro-stepped dielectric material portions 165 that are perpendicular to the first horizontal direction hd1 is defined as the first lateral extent LE1. Each first-tier retro-stepped dielectric material portion 165 overlies a respective first-tier staircase region formed in the first vertically alternating sequence (132, 142).

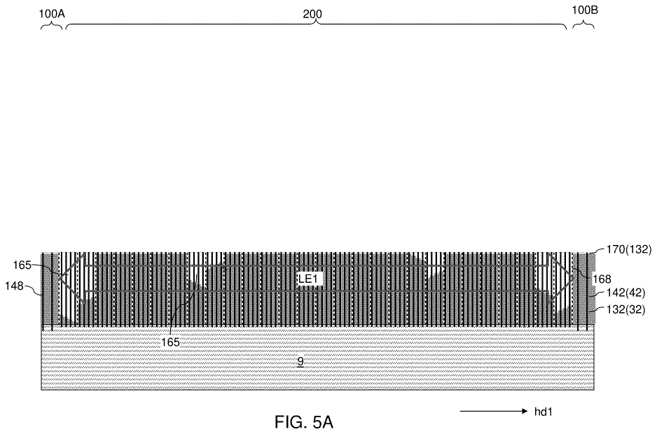

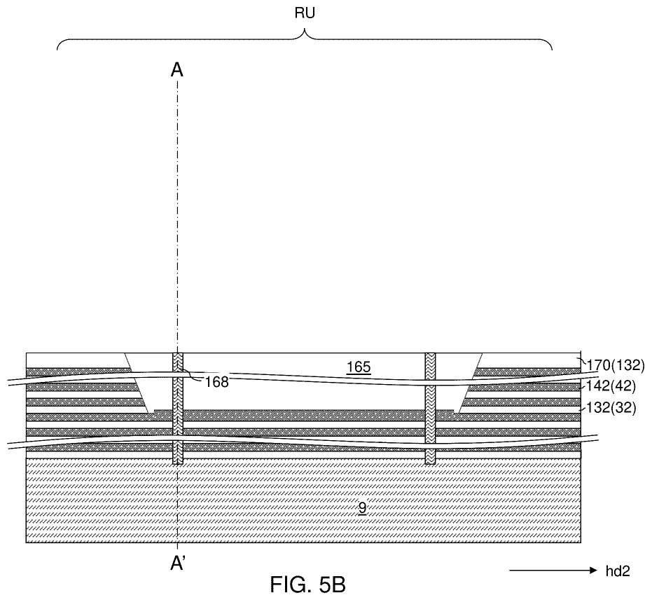

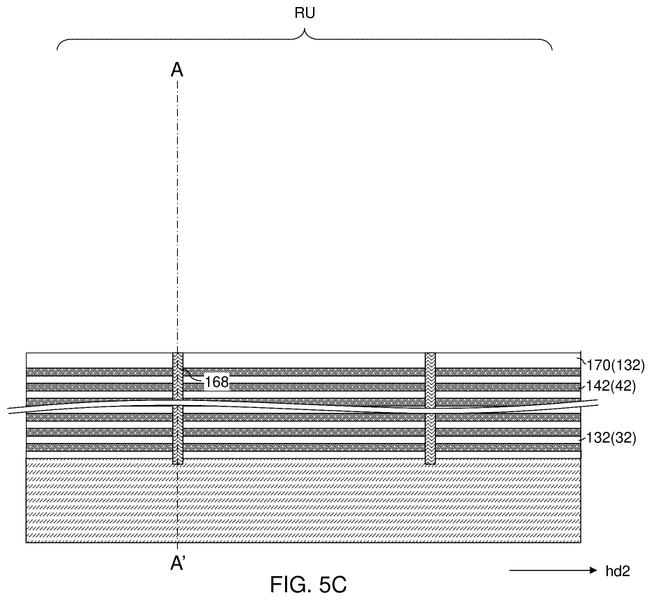

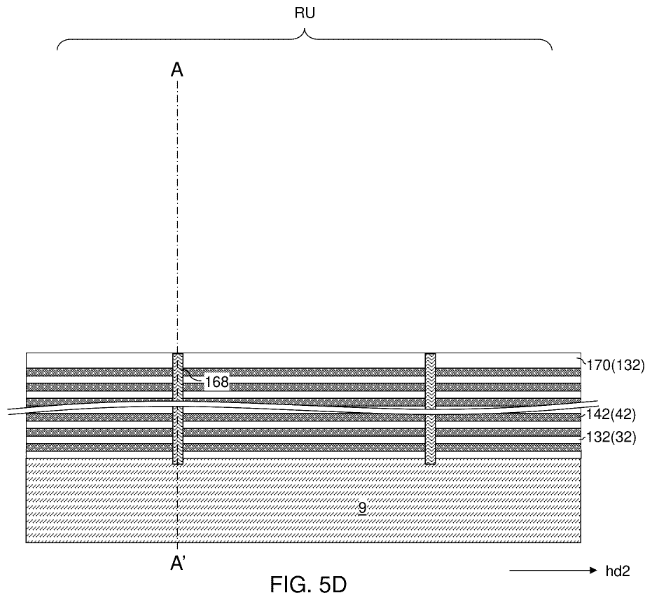

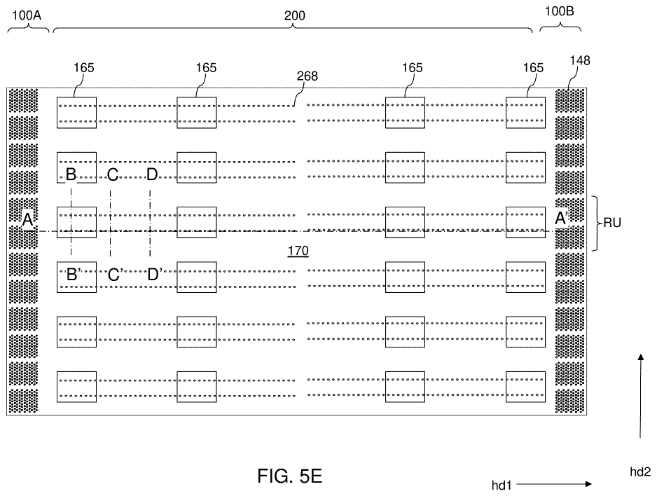

Referring to FIGS. 5A-5E, various first-tier openings may be formed through the first vertically alternating sequence (132, 142) and into the substrate 9. A photoresist layer (not shown) may be applied over the first vertically alternating sequence (132, 142), and may be lithographically patterned to form various openings therethrough. The pattern of openings in the photoresist layer may be transferred through the first vertically alternating sequence (132, 142) and into the substrate 9 by a first anisotropic etch process to form the various first-tier openings concurrently. The various first-tier openings may include first-tier memory openings formed in the memory array regions (100A, 100B) and first-tier support openings formed in the contact region 200, and first-tier contact openings formed in the staircase regions (which are located within the contact region 200).

Each cluster of first-tier memory openings may be formed as a two-dimensional array of first-tier memory openings. The first-tier support openings are openings that are formed in the contact region 200, and are subsequently employed to form support pillar structures. Each first-tier contact opening is formed in a respective area in which a respective through-via contact structure is to be subsequently formed. A subset of the first-tier support openings may be formed through a respective horizontally-extending surface segment of the first stepped surfaces. A subset of the first-tier contact openings is formed through a respective horizontally-extending surface segment of the first stepped surfaces.

Sacrificial first-tier opening fill structures (148, 168) may be formed in the various first-tier openings. For example, a sacrificial first-tier fill material is concurrently deposited in each of the first-tier openings. The sacrificial first-tier fill material includes a material that may be subsequently removed selectively to the materials of the first-tier insulating layers 132 and the first-tier sacrificial material layers 142. In one embodiment, the sacrificial first-tier fill material may include a semiconductor material such as silicon (e.g., amorphous or polysilicon), silicon-germanium, germanium, a III-V compound semiconductor material, or a combination thereof. Optionally, a thin etch stop liner (such as a silicon oxide layer or a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In another embodiment, the sacrificial first-tier fill material may include a silicon oxide material having a higher etch rate than the material of the first-tier insulating layers 132. For example, the sacrificial first-tier fill material may include borosilicate glass or porous or non-porous organosilicate glass having an etch rate that is at least 100 times higher than the etch rate of densified TEOS oxide (i.e., a silicon oxide material formed by decomposition of tetraethylorthosilicate glass in a chemical vapor deposition process and subsequently densified in an anneal process) in a 100:1 dilute hydrofluoric acid. In this case, a thin etch stop liner (such as a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

Portions of the deposited sacrificial first-tier fill material may be removed from above the topmost layer of the first vertically alternating sequence (132, 142), such as from above the first-tier insulating cap layer 170. For example, the sacrificial first-tier fill material may be recessed to a top surface of the first-tier insulating cap layer 170 using a planarization process. The planarization process may include a recess etch, chemical mechanical planarization (CMP), or a combination thereof. The top surface of the first-tier insulating cap layer 170 may be used as an etch stop layer or a planarization stop layer.

Remaining portions of the sacrificial first-tier fill material comprise sacrificial first-tier opening fill structures (148, 168). Specifically, each remaining portion of the sacrificial first-tier fill material in a first-tier memory opening constitutes a sacrificial first-tier memory opening fill structure 148. Each remaining portion of the sacrificial first-tier fill material in a first-tier support opening constitutes a sacrificial first-tier support opening fill structure (not illustrated for the sake of reducing complexity of the drawings). Each remaining portion of the sacrificial first-tier fill material in a first-tier contact opening constitutes a sacrificial first-tier contact opening fill structure 168. The various sacrificial first-tier opening fill structures (148, 168) are concurrently formed, i.e., employing a same set of processes including the deposition process that deposits the sacrificial first-tier fill material and the planarization process that removes the first-tier deposition process from above the first vertically alternating sequence (132, 142) (such as from above the top surface of the first-tier insulating cap layer 170). The top surfaces of the sacrificial first-tier opening fill structures (148, 168) may be coplanar with the top surface of the first-tier insulating cap layer 170. Each of the sacrificial first-tier opening fill structures (148, 168) may optionally include cavities therein. The set of all structures located between the bottommost surface of the first vertically alternating sequence (132, 142) and the topmost surface of the first vertically alternating sequence (132, 142) or embedded within the first vertically alternating sequence (132, 142) constitutes a first-tier structure.

According to an aspect of the present disclosure, each first-tier sacrificial material layer 142 comprises a respective locally thickened portion underneath each first-tier retro-stepped dielectric material portion 165. A subset of the first-tier contact openings can be formed through a locally thickened portion of a respective first-tier sacrificial material layer 142. The sacrificial first-tier contact opening fill structures 168 may vertically extend from a horizontal plane including a top surface of the first-tier alternating stack (132, 142) at least to a horizontal plane including a bottom surface of the first-tier alternating stack (132, 142).

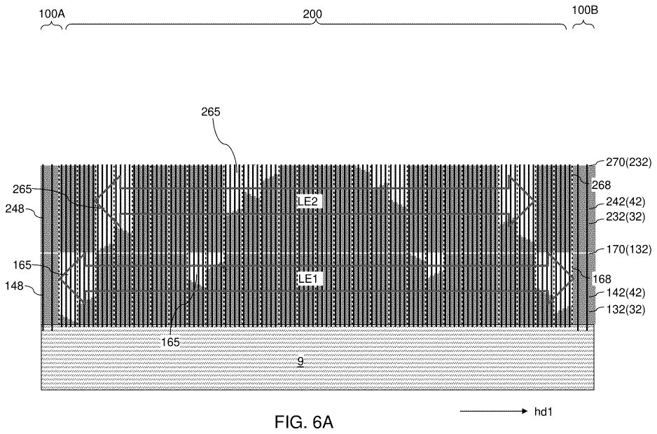

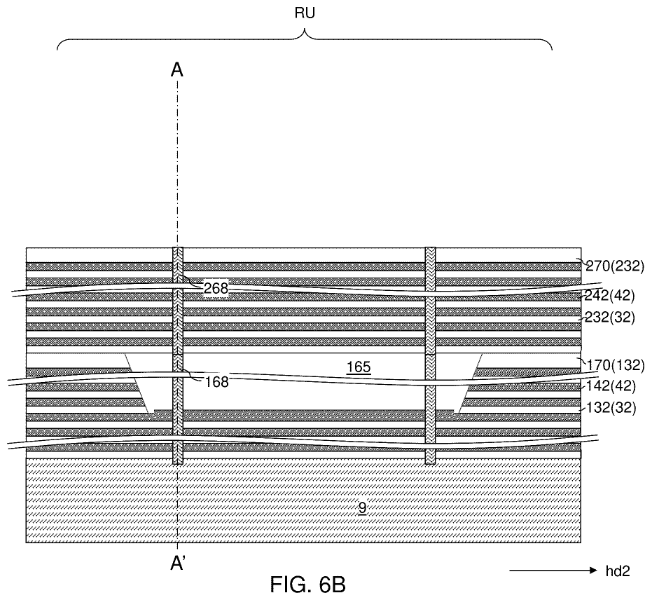

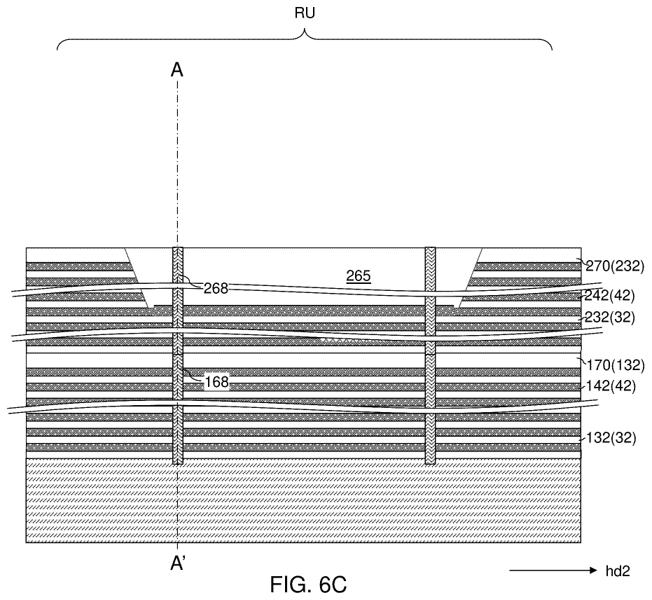

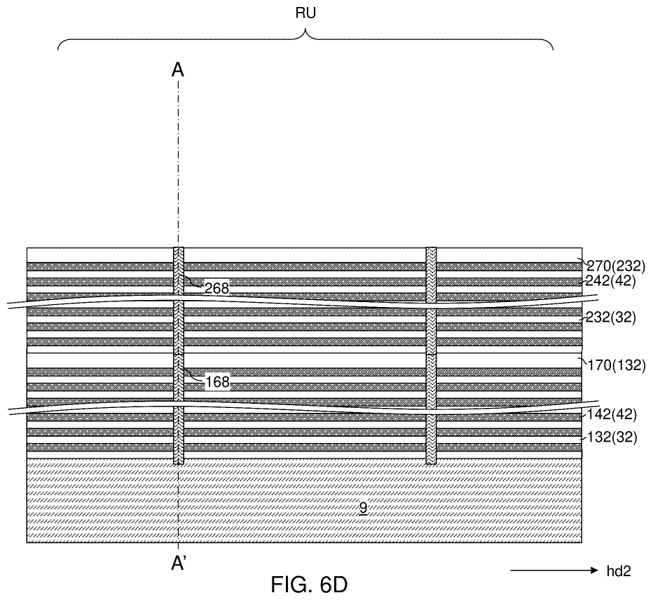

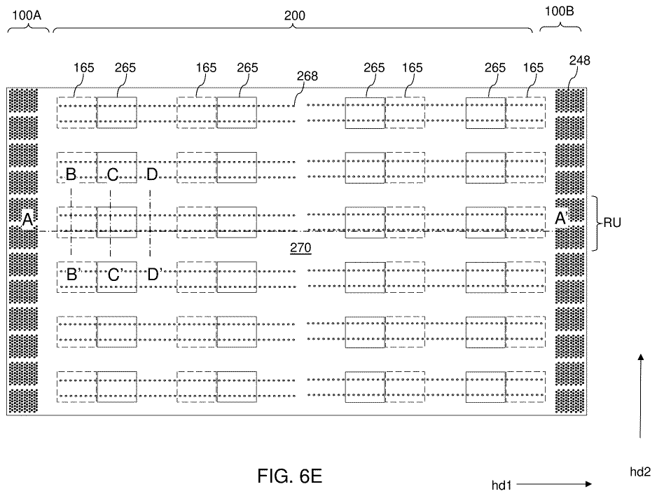

Referring to FIGS. 6A-6E, a second vertically alternating sequence of second-tier insulating layers 232 and second-tier sacrificial material layers 242 can be formed. Each of the second-tier insulating layers 232 is an insulating layer 32 that continuously extends over the entire area of the substrate 9, and may have a uniform thickness throughout. Each of the second-tier sacrificial material layers 242 is a sacrificial material layer 42 that includes a dielectric material and continuously extends over the entire area of the substrate 9, and may have a uniform thickness throughout. The second-tier insulating layers 232 can have the same material composition and the same thickness as the first-tier insulating layers 132. The second-tier sacrificial material layers 242 can have the same material composition and the same thickness as the first-tier sacrificial material layers 142. The topmost second-tier insulating layer 232 is herein referred to as a second-tier insulating cap layer 270. The second-tier insulating cap layer 270 may have a greater thickness than each of the underlying second-tier insulating layers 232.

Second stepped surfaces can be formed within each second-tier stepped cavity in the contact region 200 which will be filled with a respective second-tier retro-stepped dielectric material portions 265. For example, a combination of a sacrificial hard mask layer and a trimming mask layer may be employed to form the second stepped surfaces. Generally, the processing steps described with reference to FIGS. 2A-2E can be performed with a change in the masking pattern to form second-tier stepped cavities. Each set of second stepped surfaces may be laterally offset along the first horizontal direction hd1 relative to an adjacent and underlying set of first stepped surfaces of the first vertically alternating sequence (132, 142).

Each second-tier stepped cavity comprises a respective contiguous set of stepped surfaces of the second vertically alternating sequence (232, 242). The lateral extents of the second-tier sacrificial material layers 242 vary with a vertical distance from the substrate 9 in each second-tier stepped cavity. Each of the second-tier sacrificial material layers 242 has a respective physically exposed horizontal top surface segment within each second-tier stepped cavity.

The sidewalls of each second-tier staircase region may be tapered. The area in which the physically exposed horizontal surface segments of the second-tier stepped surfaces of a second-tier stepped cavity is located within a plan view is herein referred to as a second-tier stepped surface area. According to an aspect of the present disclosure, the second-tier stepped surface areas do not have any areal overlap with the first-tier stepped surface areas in the plan view.

In one embodiment, each first-tier stepped surface area may have a rectangular shape in the plan view. In one embodiment, the lateral extent of each of the second-tier stepped surface area along the first horizontal direction hd1 may be different than the lateral extent of each of the first-tier stepped surface area along the first horizontal direction hd1. Physically-exposed portions of the second-tier sacrificial material layers 242 may be locally thickened by performing a sequence of processing steps described with reference to FIGS. 3A-3C or by performing a sequence of processing steps described with reference to FIGS. 4A-4E.

A second dielectric fill material (such as undoped silicate glass (i.e., silicon oxide) or a doped silicate glass) can be deposited in each second-tier stepped cavity. The second dielectric fill material can be planarized to remove excess portions of the second dielectric fill material from above the horizontal plane including the topmost surface of the second vertically alternating sequence (232, 242). Each remaining portion of the second dielectric fill material that fills a respective second-tier stepped cavity constitutes a second-tier retro-stepped dielectric material portion 265. Generally, the second-tier retro-stepped dielectric material portions 265 can be formed in the contact region 200 located between the first memory array region 100A and the second memory array region 100B. The planar top surface of each second-tier retro-stepped dielectric material portion 265 can be located within a horizontal plane including the top surface of the second-tier insulating cap layer 270.

Each repetition unit RU comprises a respective set of second-tier retro-stepped dielectric material portions 265 overlying respective second-tier staircase regions in the second vertically alternating sequence (232, 242). In one embodiment, each second-tier retro-stepped dielectric material portion 265 comprises at least one ascending staircase bottom surface containing first horizontal surface segments of which vertical distances from a top surface of the growth substrate 9 increase stepwise along the first horizontal direction hd1, and at least one descending staircase bottom surface containing second horizontal surface segments of which vertical distances from the top surface of the growth substrate 9 decrease stepwise along the first horizontal direction hd1.

Each repletion unit RU may comprise three or more second-tier retro-stepped dielectric material portions 265. In the illustrated example, each repetition unit RU comprises four retro-stepped dielectric material portions 265. Each second-tier retro-stepped dielectric material portion 265 has a plurality of sidewalls that are perpendicular to the second horizontal direction. As used herein, within each repetition unit RU, the maximum lateral spacing along the first horizontal direction hd1 of sidewalls of the second-tier retro-stepped dielectric material portions 265 that are perpendicular to the first horizontal direction hd1 is defined as the second lateral extent LE2.

In one embodiment, the second-tier retro-stepped dielectric material portions 265 do not have any areal overlap with the first-tier retro-stepped dielectric material portions 165 in a plan view. As used herein, a plan view refers to a view in which all structural elements are projected along the vertical direction to a horizontal plane. For example, the top-down view of FIG. 6E in which the first-tier retro-stepped dielectric material portions 165 are illustrated in dotted lines is a plan view. In one embodiment, the second lateral extent LE2 is different from the first lateral extent LE1. For example, the second lateral extent LE2 may be less than the first lateral extent LE1.

The processing steps described with reference to FIGS. 5A-5E may be performed with necessary changes to form various second-tier openings through the second vertically alternating sequence (232, 242). A photoresist layer (not shown) may be applied over the second vertically alternating sequence (232, 242), and may be lithographically patterned to form various openings therethrough. The pattern of openings in the photoresist layer may be transferred through the second vertically alternating sequence (232, 242) by a second anisotropic etch process to form the various second-tier openings concurrently. The various second-tier openings may include second-tier memory openings formed in the memory array region 200 and second-tier support openings (not illustrated for the sake of reducing the complexity in the drawings) formed in the contact region 200, and second-tier contact openings formed in the staircase regions (which are located within the contact region 200). Each cluster of second-tier memory openings may be formed as a two-dimensional array of second-tier memory openings. The second-tier support openings are openings that are formed in the contact region 200, and are subsequently employed to form support pillar structures. Each second-tier contact opening is formed in a respective area in which a respective through-via contact structure is to be subsequently formed. A subset of the second-tier support openings may be formed through a respective horizontally-extending surface segment of the second stepped surfaces. A subset of the second-tier contact openings is formed through a respective horizontally-extending surface segment of the second stepped surfaces.

Sacrificial second-tier opening fill structures (248, 268) may be formed in the various second-tier openings. For example, a sacrificial second-tier fill material is concurrently deposited in each of the second-tier openings. The sacrificial second-tier fill material and an optional thin etch stop liner may be the same as described above. The sacrificial second-tier fill material may be formed by a non-conformal deposition or a conformal deposition method. Portions of the deposited sacrificial second-tier fill material may be removed from above the topmost layer of the second vertically alternating sequence (232, 242), such as from above the second-tier insulating cap layer 270. For example, the sacrificial second-tier fill material may be recessed to a top surface of the second-tier insulating cap layer 270 using a planarization process. The planarization process may include a recess etch, chemical mechanical planarization (CMP), or a combination thereof. The top surface of the second-tier insulating cap layer 270 may be used as an etch stop layer or a planarization stop layer.

Remaining portions of the sacrificial second-tier fill material comprise sacrificial second-tier opening fill structures (248, 268). Specifically, each remaining portion of the sacrificial second-tier fill material in a second-tier memory opening constitutes a sacrificial second-tier memory opening fill structure 248. Each remaining portion of the sacrificial second-tier fill material in a second-tier support opening constitutes a sacrificial second-tier support opening fill structure (not illustrated for the sake of reducing complexity of the drawings). Each remaining portion of the sacrificial second-tier fill material in a second-tier contact opening constitutes a sacrificial second-tier contact opening fill structure 268. The various sacrificial second-tier opening fill structures (248, 268) are concurrently formed, i.e., during a same set of processes including the deposition process that deposits the sacrificial second-tier fill material and the planarization process that removes the second-tier deposition process from above the second vertically alternating sequence (232, 242) (such as from above the top surface of the second-tier insulating cap layer 270). The top surfaces of the sacrificial second-tier opening fill structures (248, 268) may be coplanar with the top surface of the second-tier insulating cap layer 270. Each of the sacrificial second-tier opening fill structures (248, 268) may optionally include cavities therein. The set of all structures located between the bottommost surface of the second vertically alternating sequence (232, 242) and the topmost surface of the second vertically alternating sequence (232, 242) or embedded within the second vertically alternating sequence (232, 242) constitutes a second-tier structure.

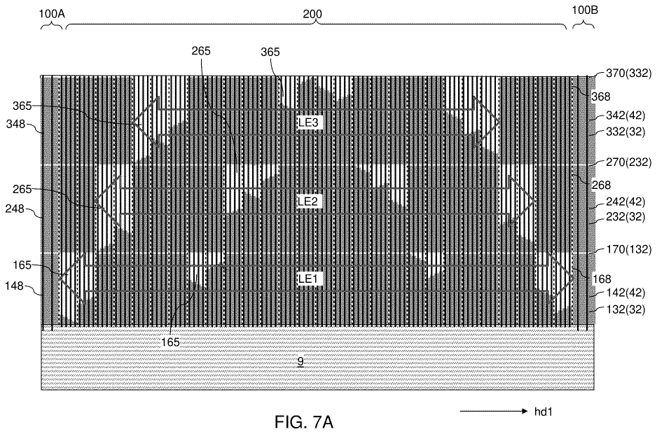

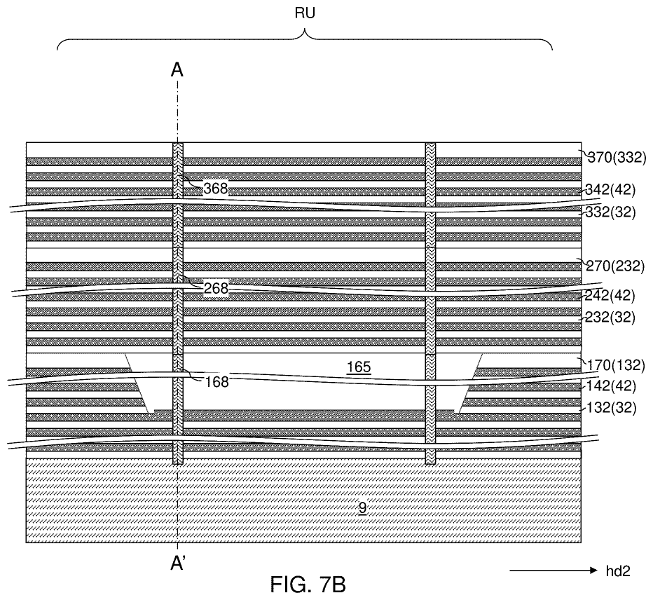

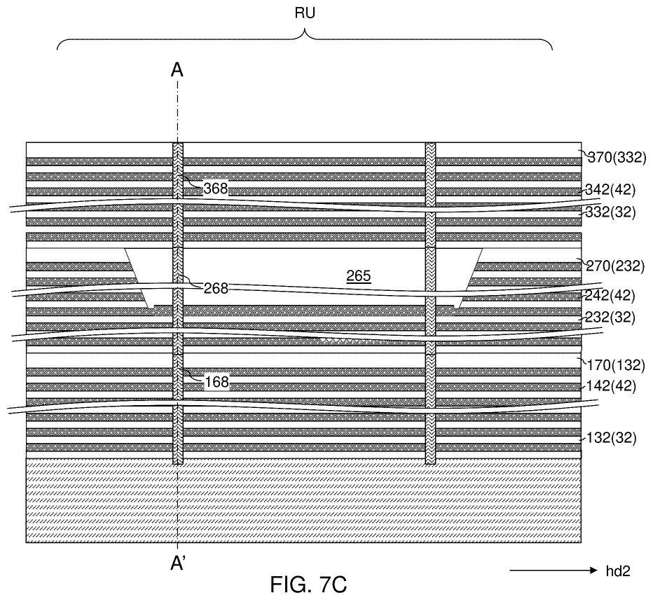

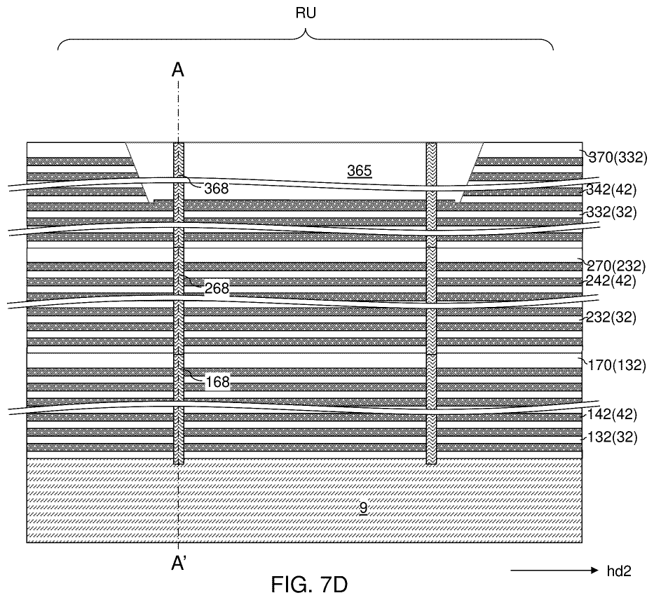

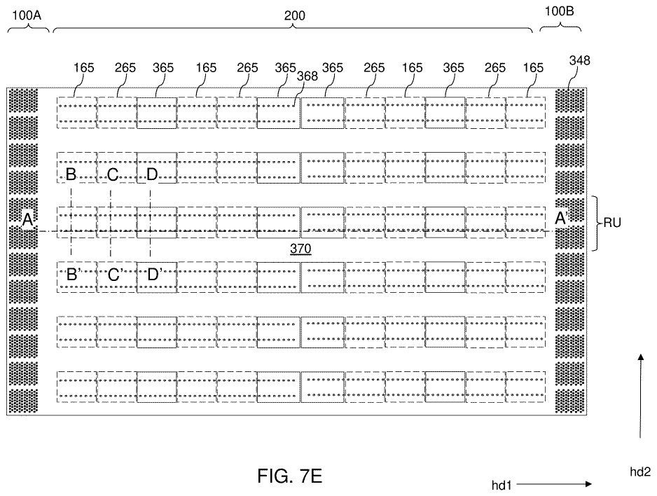

Referring to FIGS. 7A-7E, a third vertically alternating sequence of third-tier insulating layers 332 and third-tier sacrificial material layers 342 can be formed. Each of the third-tier insulating layers 332 is an insulating layer 32 that continuously extends over the entire area of the substrate 9, and may have a uniform thickness throughout. Each of the third-tier sacrificial material layers 342 is a sacrificial material layer 42 that includes a dielectric material and continuously extends over the entire area of the substrate 9, and may have a uniform thickness throughout. The third-tier insulating layers 332 can have the same material composition and the same thickness as the first-tier insulating layers 132. The third-tier sacrificial material layers 342 can have the same material composition and the same thickness as the first-tier sacrificial material layers 142. The topmost third-tier insulating layer 332 is herein referred to as a third-tier insulating cap layer 370. The third-tier insulating cap layer 370 may have a greater thickness than each of the underlying third-tier insulating layers 332.

Third stepped surfaces can be formed within each third-tier stepped cavity in the contact region 200 which will be filled with a respective third-tier retro-stepped dielectric material portions 365. For example, a combination of a sacrificial hard mask layer and a trimming mask layer may be employed to form the third stepped surfaces. Generally, the processing steps described with reference to FIGS. 3A-3E can be performed with a change in the masking pattern to form third-tier stepped cavities. Each set of third stepped surfaces may be laterally offset along the first horizontal direction hd1 relative to an adjacent and underlying set of second stepped surfaces of the second vertically alternating sequence (232, 242).

Each third-tier stepped cavity comprises a respective contiguous set of stepped surfaces of the third vertically alternating sequence (332, 342). The lateral extents of the third-tier sacrificial material layers 342 vary with a vertical distance from the substrate 9 in each third-tier stepped cavity. Each of the third-tier sacrificial material layers 342 has a respective physically exposed horizontal top surface segment within each third-tier stepped cavity.

The sidewalls of each third-tier staircase region may be tapered. The area in which the physically exposed horizontal surface segments of the third-tier stepped surfaces of a third-tier stepped cavity is located within a plan view is herein referred to as a third-tier stepped surface area. According to an aspect of the present disclosure, the third-tier stepped surface areas do not have any areal overlap with the first-tier stepped surface areas in the plan view, and do not have any areal overlap with the second-tier stepped surface areas in the plan view.

In one embodiment, each first-tier stepped surface area may have a rectangular shape in the plan view. In one embodiment, the lateral extent of each of the third-tier stepped surface area along the first horizontal direction hd1 may be different than the lateral extent of each of the first-tier stepped surface area along the first horizontal direction hd1. Physically-exposed portions of the third-tier sacrificial material layers 342 may be locally thickened by performing a sequence of processing steps described with reference to FIGS. 3A-3C or by performing a sequence of processing steps described with reference to FIGS. 4A-4E.

A third dielectric fill material (such as undoped silicate glass (i.e., silicon oxide) or a doped silicate glass) can be deposited in each third-tier stepped cavity. The third dielectric fill material can be planarized to remove excess portions of the third dielectric fill material from above the horizontal plane including the topmost surface of the third vertically alternating sequence (332, 342). Each remaining portion of the third dielectric fill material that fills a respective third-tier stepped cavity constitutes a third-tier retro-stepped dielectric material portion 365. Generally, the third-tier retro-stepped dielectric material portions 365 can be formed in the contact region 200 located between the first memory array region 100A and the third memory array region 100B. The planar top surface of each third-tier retro-stepped dielectric material portion 365 can be located within a horizontal plane including the top surface of the third-tier insulating cap layer 370.

Each repetition unit RU comprises a respective set of third-tier retro-stepped dielectric material portions 365 overlying respective third-tier staircase regions in the third vertically alternating sequence (332, 342). In one embodiment, each third-tier retro-stepped dielectric material portion 365 comprises at least one ascending staircase bottom surface containing first horizontal surface segments of which vertical distances from a top surface of the growth substrate 9 increase stepwise along the first horizontal direction hd1, and at least one descending staircase bottom surface containing third horizontal surface segments of which vertical distances from the top surface of the growth substrate 9 decrease stepwise along the first horizontal direction hd1.

Each repletion unit RU may comprise three or more third-tier retro-stepped dielectric material portions 365. In the illustrated example, each repetition unit RU comprises four retro-stepped dielectric material portions 365. Each third-tier retro-stepped dielectric material portion 365 has a plurality of sidewalls that are perpendicular to the third horizontal direction. As used herein, within each repetition unit RU, the maximum lateral spacing along the first horizontal direction hd1 of sidewalls of the third-tier retro-stepped dielectric material portions 365 that are perpendicular to the first horizontal direction hd1 is defined as the third lateral extent LE3.

In one embodiment, the third-tier retro-stepped dielectric material portions 365 do not have any areal overlap with the first-tier retro-stepped dielectric material portions 165 in the plan view, and do not have any areal overlap with the second-tier retro-stepped dielectric material portions 265 in the plan view. In one embodiment, the third lateral extent LE3 is different from the first lateral extent LE1, and is different from the second lateral extent LE2. For example, the third lateral extent LE3 may be less than the first lateral extent LE1, and may be less than the second lateral extent LE2.

The processing steps described with reference to FIGS. 5A-5E may be performed with necessary changes to form various third-tier openings through the third vertically alternating sequence (332, 342). A photoresist layer (not shown) may be applied over the third vertically alternating sequence (332, 342), and may be lithographically patterned to form various openings therethrough. The pattern of openings in the photoresist layer may be transferred through the third vertically alternating sequence (332, 342) by a third anisotropic etch process to form the various third-tier openings concurrently. The various third-tier openings may include third-tier memory openings formed in the memory array region 200 and third-tier support openings (not illustrated for the sake of reducing the complexity in the drawings) formed in the contact region 200, and third-tier contact openings formed in the staircase regions (which are located within the contact region 200). Each cluster of third-tier memory openings may be formed as a two-dimensional array of third-tier memory openings. The third-tier support openings are openings that are formed in the contact region 200, and are subsequently employed to form support pillar structures. Each third-tier contact opening is formed in a respective area in which a respective through-via contact structure is to be subsequently formed. A subset of the third-tier support openings may be formed through a respective horizontally-extending surface segment of the third stepped surfaces. A subset of the third-tier contact openings is formed through a respective horizontally-extending surface segment of the third stepped surfaces.

Sacrificial third-tier opening fill structures (348, 368) may be formed in the various third-tier openings. For example, a sacrificial third-tier fill material is concurrently deposited in each of the third-tier openings. The sacrificial third-tier fill material and an optional thin etch stop liner may be the same as described above. The sacrificial third-tier fill material may be formed by a non-conformal deposition or a conformal deposition method. Portions of the deposited sacrificial third-tier fill material may be removed from above the topmost layer of the third vertically alternating sequence (332, 342), such as from above the third-tier insulating cap layer 370. For example, the sacrificial third-tier fill material may be recessed to a top surface of the third-tier insulating cap layer 370 using a planarization process. The planarization process may include a recess etch, chemical mechanical planarization (CMP), or a combination thereof. The top surface of the third-tier insulating cap layer 370 may be used as an etch stop layer or a planarization stop layer.

Remaining portions of the sacrificial third-tier fill material comprise sacrificial third-tier opening fill structures (348, 368). Specifically, each remaining portion of the sacrificial third-tier fill material in a third-tier memory opening constitutes a sacrificial third-tier memory opening fill structure 348. Each remaining portion of the sacrificial third-tier fill material in a third-tier support opening constitutes a sacrificial third-tier support opening fill structure (not illustrated for the sake of reducing complexity of the drawings). Each remaining portion of the sacrificial third-tier fill material in a third-tier contact opening constitutes a sacrificial third-tier contact opening fill structure 368. The various sacrificial third-tier opening fill structures (348, 368) are concurrently formed, i.e., during a same set of processes including the deposition process that deposits the sacrificial third-tier fill material and the planarization process that removes the third-tier deposition process from above the third vertically alternating sequence (332, 342) (such as from above the top surface of the third-tier insulating cap layer 370). The top surfaces of the sacrificial third-tier opening fill structures (348, 368) may be coplanar with the top surface of the third-tier insulating cap layer 370. Each of the sacrificial third-tier opening fill structures (348, 368) may optionally include cavities therein. The set of all structures located between the bottommost surface of the third vertically alternating sequence (332, 342) and the topmost surface of the third vertically alternating sequence (332, 342) or embedded within the third vertically alternating sequence (332, 342) constitutes a third-tier structure.

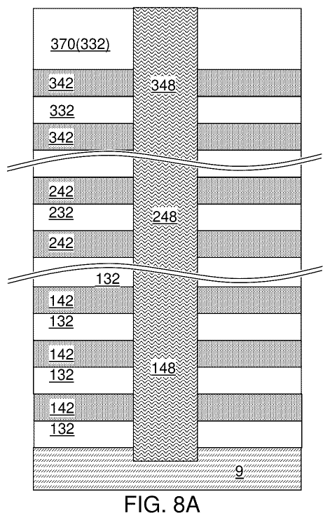

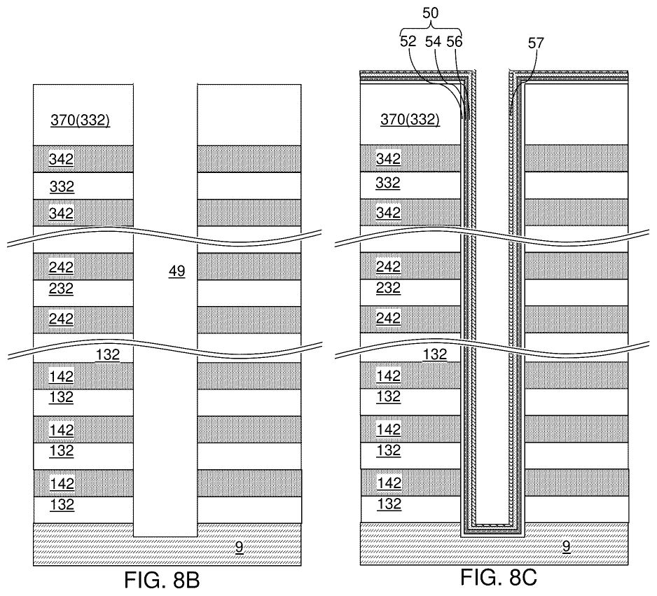

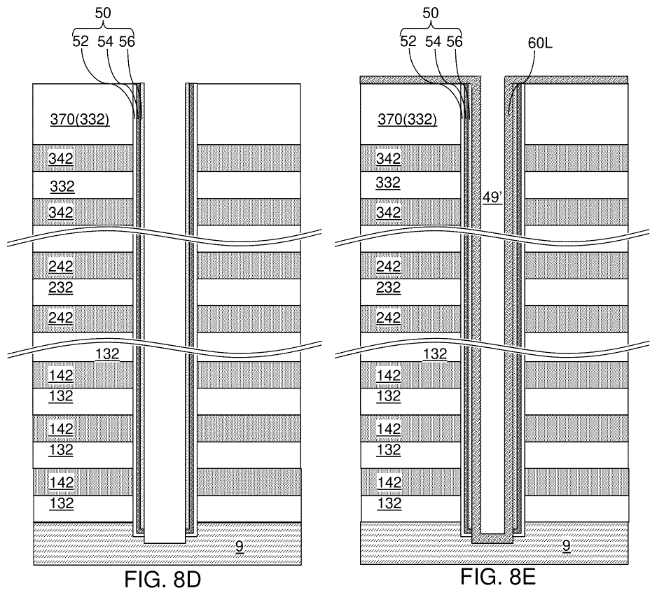

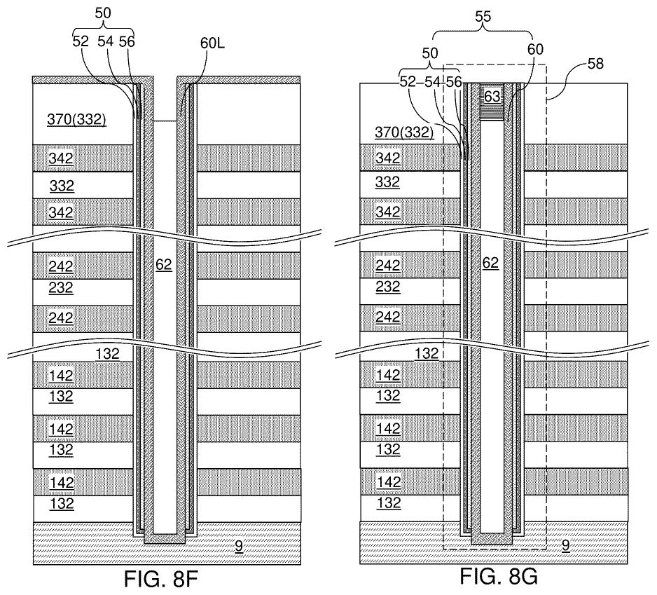

FIGS. 8A-8G illustrate sequential vertical cross-sectional views of a memory opening during formation of a memory opening fill structure according to an embodiment of the present disclosure.

Referring to FIG. 8A, a region including a vertical stack of a first-tier sacrificial memory opening fill structure 148, a second-tier sacrificial memory opening fill structure 248, and a third-tier sacrificial memory opening fill structure 348 is illustrated.

Referring to FIG. 8B, a photoresist layer (not shown) can be applied over the third-tier structure, and can be lithographically patterned to cover the contact regions 200 without covering the memory array regions (100A, 100B). The sacrificial fill materials of the sacrificial memory opening fill structures (148, 248, 348) can be removed selectively to the materials of the insulating layers 32, the sacrificial material layers 42, and the substrate 9. Memory openings 49 are formed in the voids from which the sacrificial fill materials of the sacrificial memory opening fill structures (148, 248, 348) are removed.

Referring to FIG. 8C, a stack of layers including a blocking dielectric layer 52, a memory material layer 54, a dielectric liner 56, and an optional sacrificial cover layer 57 may be sequentially deposited in the inter-tier memory openings 49. The blocking dielectric layer 52 may include a single dielectric material layer or a stack of a plurality of dielectric material layers. In one embodiment, the blocking dielectric layer 52 may include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 may include a dielectric metal oxide having a dielectric constant greater than 7.9, i.e., having a dielectric constant greater than the dielectric constant of silicon nitride. The thickness of the dielectric metal oxide layer may be in a range from 1 nm to 20 nm, although lesser and greater thicknesses may also be used. The dielectric metal oxide layer may subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 may include a dielectric semiconductor compound such as silicon oxide, silicon oxynitride, silicon nitride, or a combination thereof.

Subsequently, the memory material layer 54 may be formed. Generally, the memory material layer 54 may comprise any memory material known in the art. In one embodiment, the memory material layer 54 may be a continuous layer or patterned discrete portions of a charge trapping material including a dielectric charge trapping material, which may be, for example, silicon nitride. Alternatively, the memory material layer 54 may include a continuous layer or patterned discrete portions of a conductive material such as doped polysilicon or a metallic material that is patterned into multiple electrically isolated portions (e.g., floating gates), for example, by being formed within lateral recesses into sacrificial material layers 42. In one embodiment, the memory material layer 54 includes a silicon nitride layer. In one embodiment, the sacrificial material layers 42 and the insulating layers 32 may have vertically coincident sidewalls, and the memory material layer 54 may be formed as a single continuous layer. Alternatively, the sacrificial material layers 42 may be laterally recessed with respect to the sidewalls of the insulating layers 32, and a combination of a deposition process and an anisotropic etch process may be used to form the memory material layer 54 as a plurality of memory material portions that are vertically spaced apart. The thickness of the memory material layer 54 may be in a range from 2 nm to 20 nm, although lesser and greater thicknesses may also be used.

The dielectric liner 56 includes a dielectric material. In one embodiment, the dielectric liner 56 may comprise a tunneling dielectric layer through which charge tunneling may be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric liner 56 may include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric liner 56 may include a stack of a first silicon oxide layer, a silicon oxynitride layer, and a second silicon oxide layer, which is commonly known as an ONO stack. In one embodiment, the dielectric liner 56 may include a silicon oxide layer that is substantially free of carbon or a silicon oxynitride layer that is substantially free of carbon. The thickness of the dielectric liner 56 may be in a range from 2 nm to 20 nm, although lesser and greater thicknesses may also be used. The stack of the blocking dielectric layer 52, the memory material layer 54, and the dielectric liner 56 constitutes a memory film 50 that stores memory bits.

The sacrificial cover layer 57 may comprise a sacrificial material that may be subsequently removed selectively to the material of the dielectric liner 56. For example, the sacrificial cover layer may comprise a semiconductor material (e.g., amorphous silicon), silicon oxide, or a carbon-based material (such as amorphous carbon or diamond-like carbon). The thickness of the sacrificial cover layer may be in a range from 1 nm to 10 nm, although lesser and greater thicknesses may also be employed.

Referring to FIG. 8D, an anisotropic etch process may be performed to remove horizontal portions of the sacrificial cover layer 57, the dielectric liner 56, the memory material layer 54, and the blocking dielectric layer 52. Remaining cylindrical portions of the sacrificial cover layer 57 may be removed selectively to the material of the dielectric liner 56 during the anisotropic etch process, or by an isotropic etch process (such as a wet etch process) or by ashing. Alternatively, if the sacrificial cover layer 57 comprises a semiconductor material (e.g., amorphous silicon), then it may be retained.

Referring to FIG. 8E, a semiconductor channel material layer 60L can be deposited by a conformal deposition process. The semiconductor channel material layer 60L includes a p-doped semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L may have a uniform doping. In one embodiment, the semiconductor channel material layer 60L has a p-type doping in which p-type dopants (such as boron atoms) are present at an atomic concentration in a range from 1.0×10¹²/cm³ to 1.0×10¹⁸/cm³, such as from 1.0×10¹⁴/cm³ to 1.0×10¹⁷/cm³. In one embodiment, the semiconductor channel material layer 60L includes, and/or consists essentially of, boron-doped amorphous silicon or boron-doped polysilicon. In another embodiment, the semiconductor channel material layer 60L has an n-type doping in which n-type dopants (such as phosphor atoms or arsenic atoms) are present at an atomic concentration in a range from 1.0×10¹²/cm³ to 1.0×10¹⁸/cm³, such as from 1.0×10¹⁴/cm³ to 1.0×10¹⁷/cm³. The semiconductor channel material layer 60L may be formed by a conformal deposition method such as a low pressure chemical vapor deposition (LPCVD) process. The thickness of the semiconductor channel material layer 60L may be in a range from 2 nm to 10 nm, although lesser and greater thicknesses may also be used. A cavity 49′ is formed in the volume of each inter-tier memory opening 49 that is not filled with the deposited material layers (52, 54, 56, 60L).

Referring to FIG. 8F, if the cavity 49′ in each memory opening 49 is not completely filled by the semiconductor channel material layer 60L, a dielectric core layer may be deposited in the cavity 49′ to fill any remaining portion of the cavity 49′ within each memory opening 49. The dielectric core layer includes a dielectric material such as silicon oxide or organosilicate glass. The dielectric core layer may be deposited by a conformal deposition method such as a low pressure chemical vapor deposition (LPCVD) process, or by a self-planarizing deposition process such as spin coating. The horizontal portion of the dielectric core layer overlying the third-tier insulating cap layer 370 may be removed, for example, by a recess etch. The recess etch continues until top surfaces of the remaining portions of the dielectric core layer are recessed to a height between the top and bottom surfaces of the third-tier insulating cap layer 370. Each remaining portion of the dielectric core layer constitutes a dielectric core 62.

Referring to FIG. 8G, a doped semiconductor material having a doping of a second conductivity type may be deposited in cavities overlying the dielectric cores 62. The second conductivity type is the opposite of the first conductivity type. For example, if the first conductivity type is p-type, the second conductivity type is n-type, and vice versa. Portions of the deposited doped semiconductor material, the semiconductor channel material layer 60L, the dielectric liner 56, the memory material layer 54, and the blocking dielectric layer 52 that overlie the horizontal plane including the top surface of the third-tier insulating cap layer 370 may be removed by a planarization process such as a chemical mechanical planarization (CMP) process.

Each remaining portion of the doped semiconductor material of the second conductivity type constitutes a drain region 63. The dopant concentration in the drain regions 63 may be in a range from 5.0×10¹⁸/cm³ to 2.0×10²¹/cm³, although lesser and greater dopant concentrations may also be used. The doped semiconductor material may be, for example, doped polysilicon.

Each remaining portion of the semiconductor channel material layer 60L constitutes a vertical semiconductor channel 60 through which electrical current may flow when a vertical NAND device including the vertical semiconductor channel 60 is turned on. A dielectric liner 56 is surrounded by a memory material layer 54, and laterally surrounds a vertical semiconductor channel 60. Each adjoining set of a blocking dielectric layer 52, a memory material layer 54, and a dielectric liner 56 collectively constitute a memory film 50, which may store electrical charges with a macroscopic retention time. In some embodiments, a blocking dielectric layer 52 may not be present in the memory film 50 at this step, and a blocking dielectric layer may be subsequently formed after formation of lateral recesses. As used herein, a macroscopic retention time refers to a retention time suitable for operation of a memory device as a permanent memory device such as a retention time in excess of 24 hours.

Each combination of a memory film 50 and a vertical semiconductor channel 60 within an inter-tier memory opening 49 constitutes a memory stack structure 55. The memory stack structure 55 is a combination of a vertical semiconductor channel 60, a dielectric liner 56, a plurality of memory elements comprising portions of the memory material layer 54, and an optional blocking dielectric layer 52. The memory stack structures 55 can be formed through memory array regions (100A, 100B) of the first and second vertically alternating sequences in which all layers of the first and second vertically alternating sequences are present. Each combination of a memory stack structure 55, a dielectric core 62, and a drain region 63 within an inter-tier memory opening 49 constitutes a memory opening fill structure 58. Generally, memory opening fill structures 58 are formed within the memory openings 49. Each of the memory opening fill structures 58 comprises a respective memory film 50 and a respective vertical semiconductor channel 60.

In one embodiment, each of the memory stack structures 55 comprises vertical NAND string including the respective vertical stack of memory elements (comprising portions of a memory material layer 54 located at levels of the sacrificial material layers 42) and a vertical semiconductor channel 60 that vertically extend through the sacrificial material layers 42 adjacent to the respective vertical stack of memory elements.

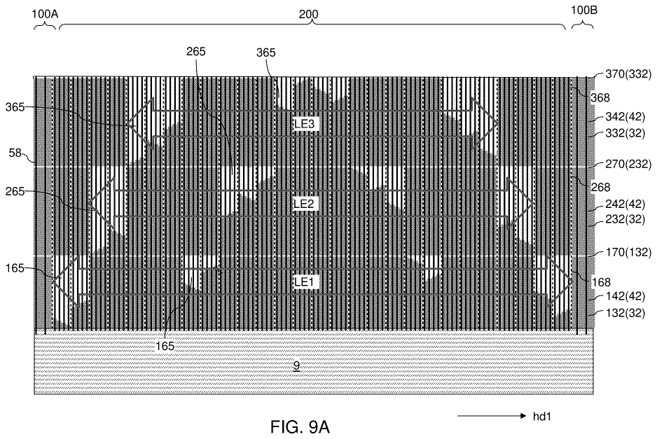

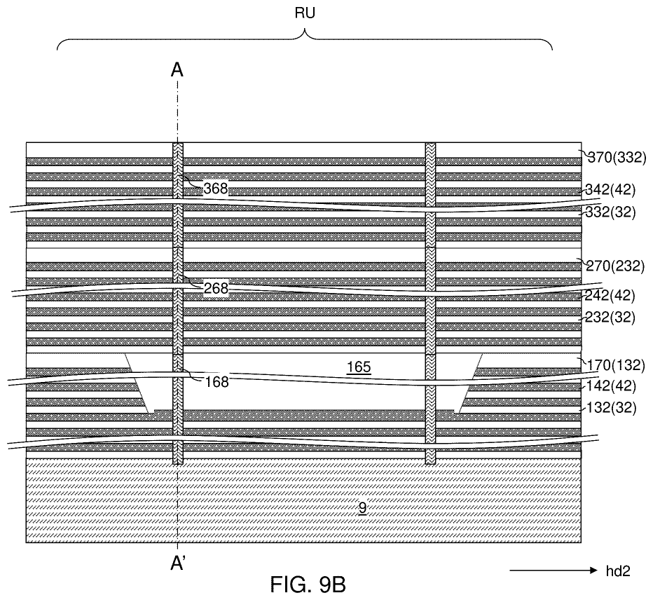

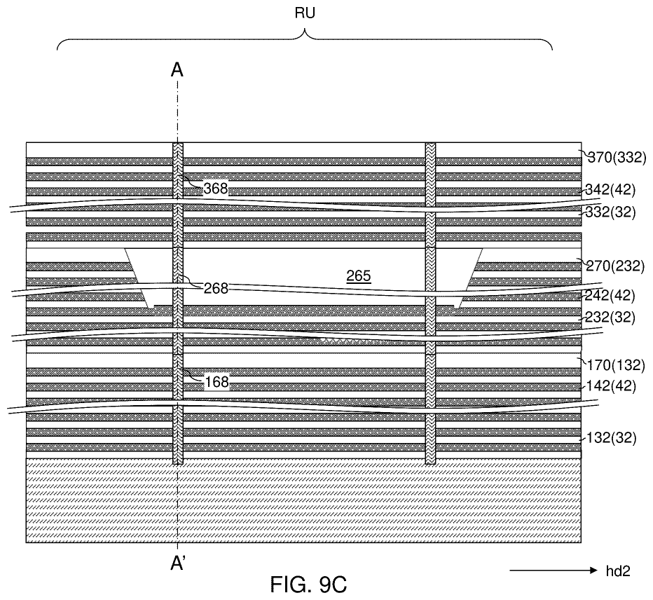

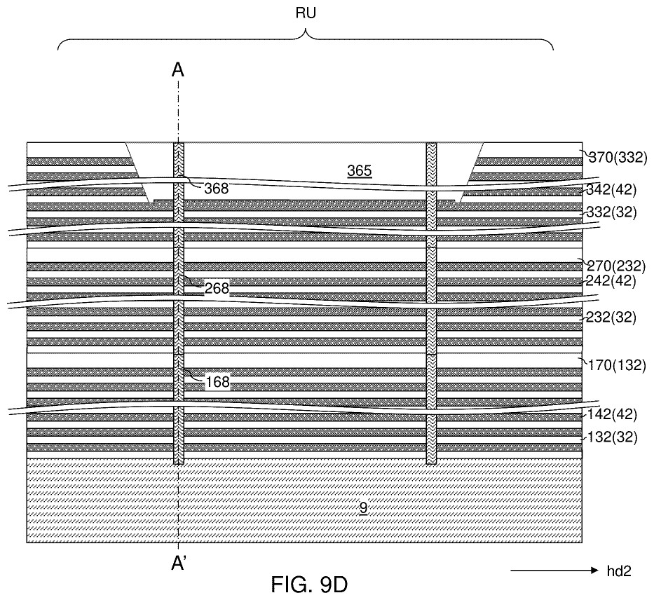

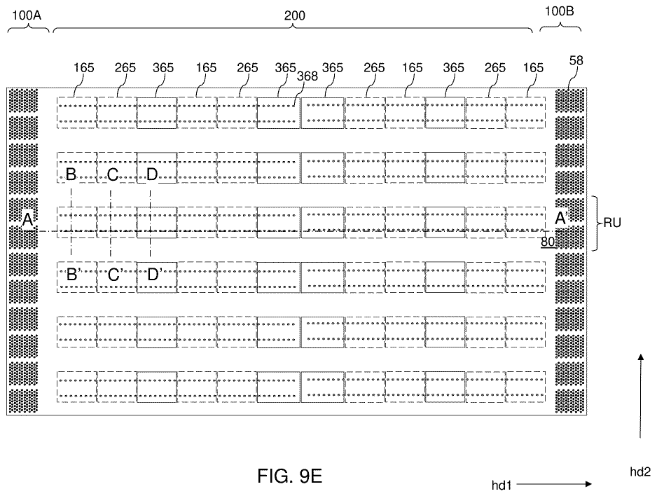

Referring to FIGS. 9A-9E, the first exemplary structure is illustrated after the processing steps of FIG. 8G, i.e., after formation of the memory opening fill structures 58 in the memory openings 49. In one embodiment, support pillar structures (not shown) may be formed in the support openings. Generally, each of the memory opening fill structures 58 comprises a respective vertical stack of memory elements located at levels of the sacrificial material layers 42 within the memory openings, and further comprises a respective vertical semiconductor channel 60 that vertically extends through the memory openings.

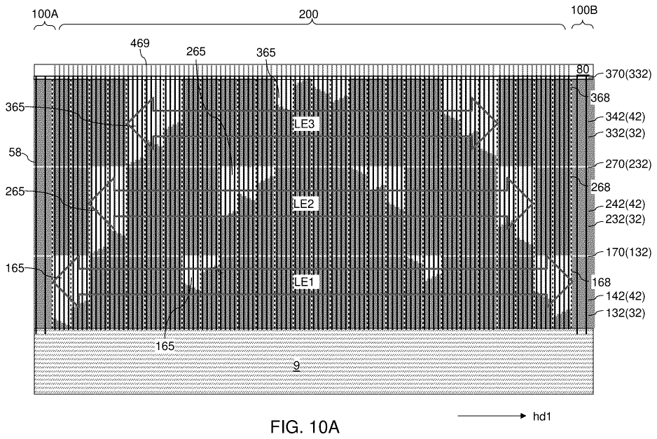

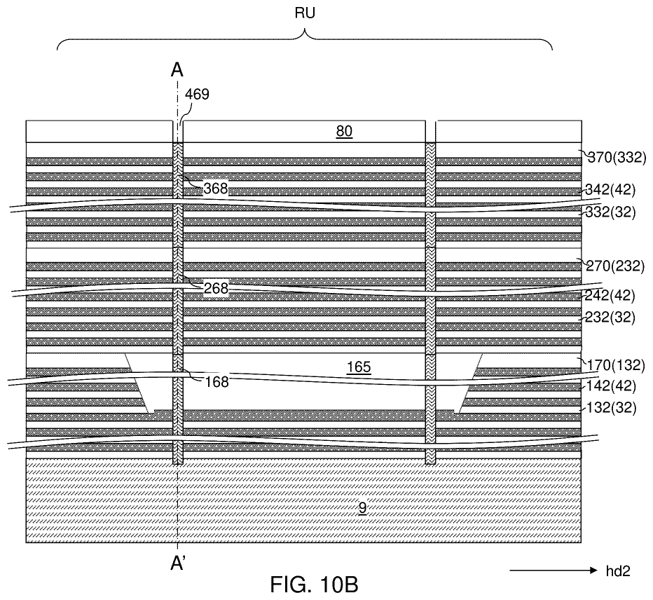

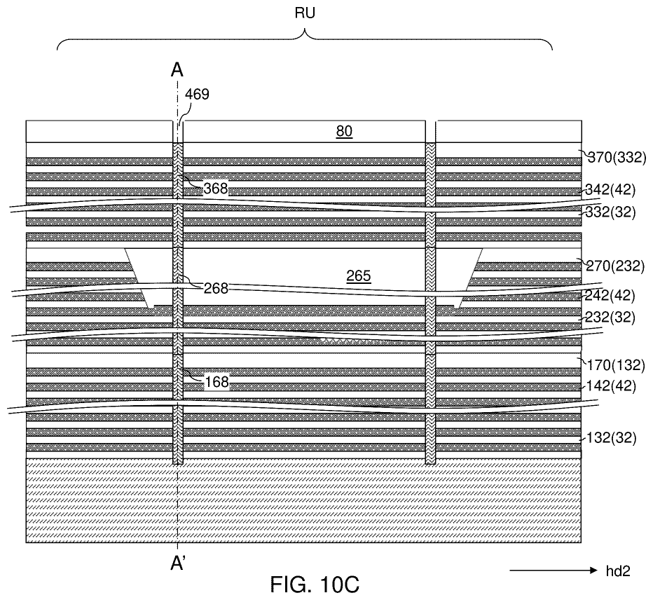

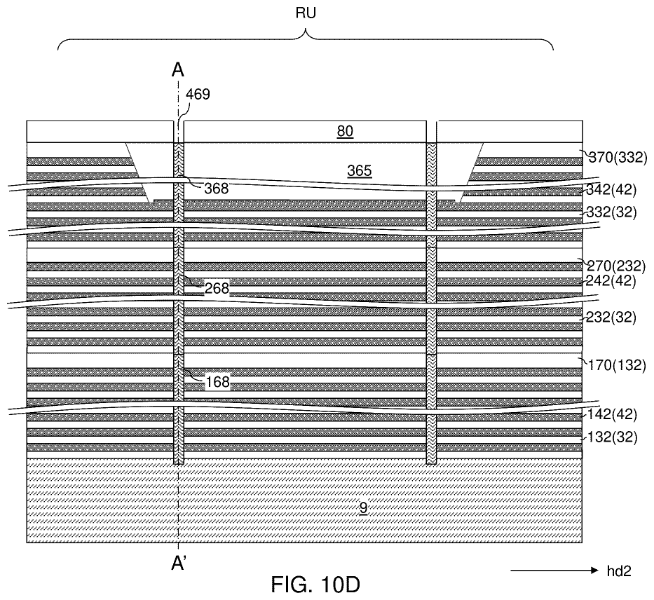

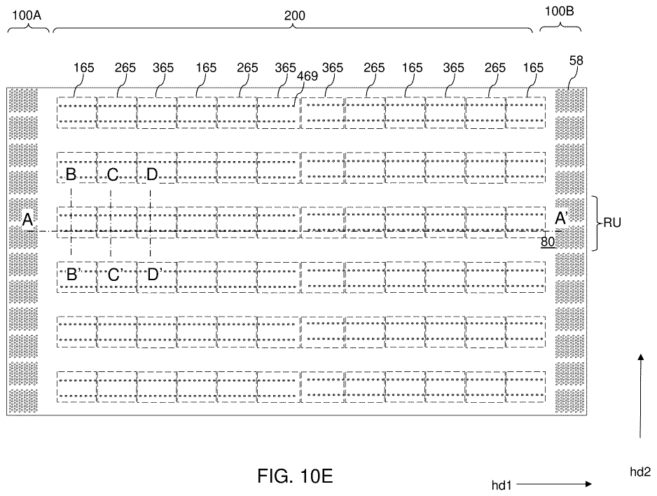

Referring to FIGS. 10A-10E, a contact-level dielectric layer 80 can be deposited over the third-tier insulating cap layer 370 and the third-tier retro-stepped dielectric material portions 365. The contact-level dielectric layer 80 comprises a dielectric material such as silicon oxide, and may have a thickness in a range from 100 nm to 800 nm, although lesser and greater thicknesses may also be employed.

A photoresist layer (not shown) can be applied over the contact-level dielectric layer 80, and can be lithographically patterned to form openings over the areas of the sacrificial third-tier contact opening fill structures 368. An anisotropic etch process can be performed to form connection cavities 469 over the sacrificial third-tier contact opening fill structures 368. The photoresist layer may be subsequently removed, for example, by ashing.

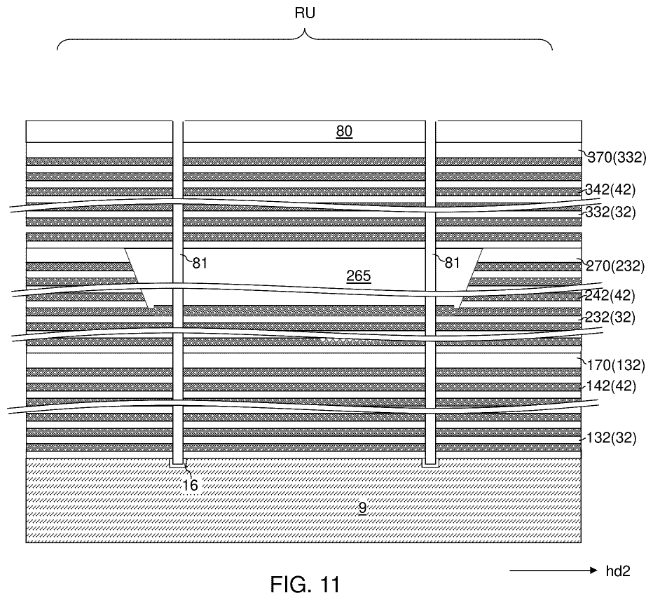

Referring to FIG. 11, the sacrificial fill materials of the sacrificial third-tier contact opening fill structures 368, the sacrificial second-tier contact opening fill structures 268, and the sacrificial first-tier contact opening fill structures 168 can be removed selectively to the materials of retro-stepped dielectric material portions (165, 265, 365), the insulating layers 32, the sacrificial material layers 42, and the support pillar structures (not shown). Contact via cavities 85 are formed in the volumes from which the materials of the sacrificial third-tier contact opening fill structures 368, the sacrificial second-tier contact opening fill structures 268, and the sacrificial first-tier contact opening fill structures 168 are removed. Each contact via cavity 85 vertically extends from the horizontal plane including the planar top surfaces of the third-tier retro-stepped dielectric material portion 365 to the substrate 9. Each contact via cavity 85 may vertically extend through a respective set of at least one insulating layer 32 and a respective set of at least one sacrificial material layer 42 of an alternating stack of insulating layers 32 and sacrificial material layers 42. Each contact via cavity 85 vertically extends through a thickened portion of the topmost sacrificial material layer within the respective set of at least one sacrificial material layer 42.

Generally, an alternating stack (32, 42) of insulating layers 32 and sacrificial material layers 42 can be formed over a substrate 9. Stepped surfaces can be formed by patterning the alternating stack (32, 42) in each staircase region. Physically exposed portions of the sacrificial material layers 42 are locally thickened after formation of the stepped surfaces. A retro-stepped dielectric material portion (165, 265, 365) is formed over the stepped surfaces. Contact via cavities 85 can be formed through a respective subset of the retro-stepped dielectric material portion (165, 265, 365) and a respective subset of the sacrificial material layers 42 within the alternating stack (32, 42). Each contact via cavity 85 may be formed through a locally thickened portion of a respective sacrificial material layer 42. Each contact via cavity 85 vertically extends through a thickened portions of only a single sacrificial material layer 42. In other words, each contact via cavity 85 vertically extends through no more than one thickened portion of the sacrificial material layers 42.

If the substrate 9 comprises a semiconductor material such as silicon, an oxidation process may be performed to convert physically exposed surface portions of the substrate 9 underneath the contact via cavities 85 into semiconductor oxide spacer liners 16. The thickness of the semiconductor oxide spacer liners 16 may be in a range from 3 nm to 8 nm, although lesser and greater thicknesses may also be employed. In one embodiment, collateral oxidation of the physically exposed surfaces of the sacrificial material layers 42 may be minimized by reducing the thickness of the semiconductor oxide spacer liners 16.

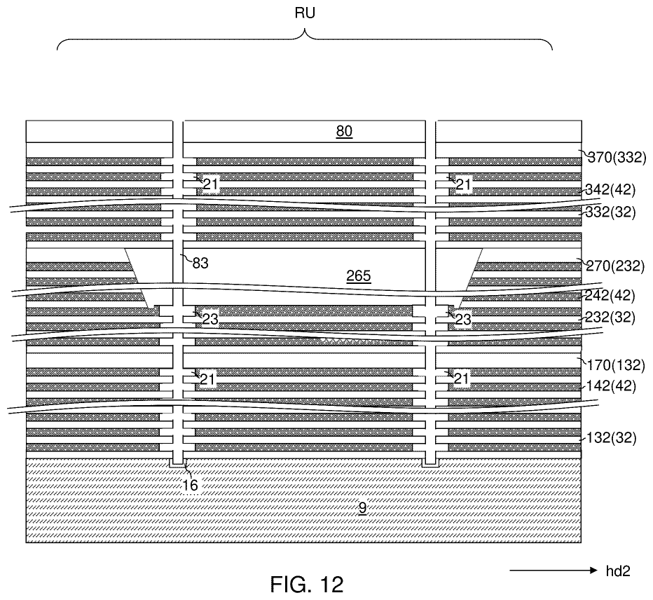

Referring to FIG. 12, a first isotropic etch process can be performed to isotropically etch proximal portions of the sacrificial material layers 42 around each contact via cavity 85 selective to the insulating layers 32 and the retro-stepped dielectric material portions (165, 265, 365). For example, if the sacrificial material layers 42 comprise silicon nitride and if the retro-stepped dielectric material portions (165, 265, 365) comprises silicon oxide, the first isotropic etch process may comprise a wet etch process employing hot phosphoric acid which etches silicon nitride selective to silicon oxide materials. The duration of the first isotropic etch process can be selected such that the lateral recess distance of the first isotropic recess etch process is in a range from 100% to 1,000%, such as from 200% to 500%, of the thickness of unthickened portions of the sacrificial material layers 42. For each contact via cavity 85 that vertically extends through at least one unthickened portion of the sacrificial material layers 42, at least one first annular recess region 21 may be formed in volumes from which material portions of sacrificial material layers-42 are removed selectively to the insulating layers 32. For each contact via cavity 85, a second annular recess region 23 can be formed by isotropically etching a proximal region of a thickened portion of a respective sacrificial material layer 23 selective to the insulating layers 32. Each contact via cavity 85 is laterally expanded at one or more levels of the sacrificial material layers 42 through formation of the annular recess regions (21, 23), and is converted into a respective laterally-expanded contact via cavity 83.

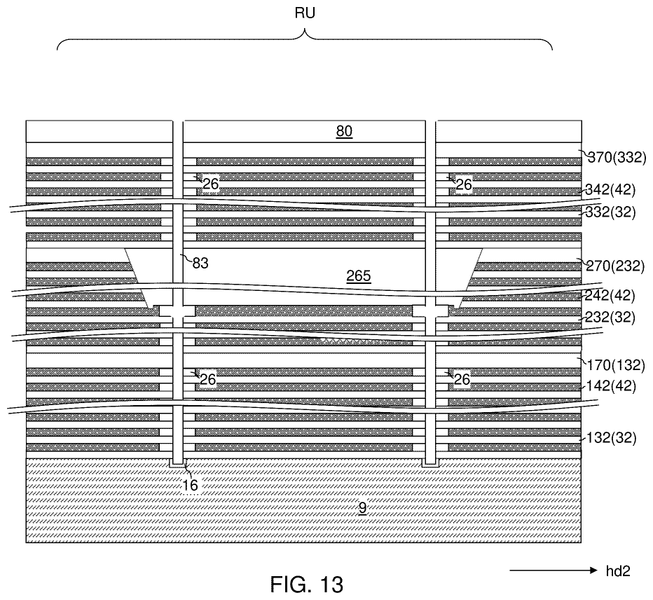

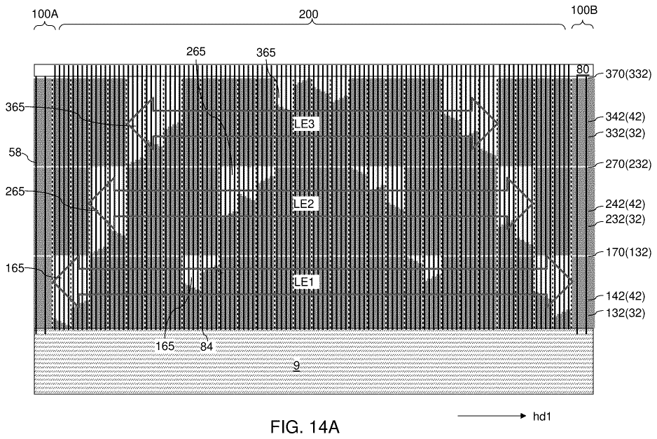

Referring to FIG. 13, a recess-fill dielectric material layer (not shown) can be formed by conformally depositing a recess-fill dielectric material, such as silicon oxide, in the first annular recess regions 21 and the second annular recess regions 23, and over sidewalls of the laterally-expanded contact via cavities 83 (i.e., contact via cavities 85 as laterally expanded by the first isotropic etch process). The thickness of the recess-fill dielectric material layer can be greater than one half of the thickness of the unthickened portions of the sacrificial material layers 42, and can be less than one half of the thickness of the thickened portions of the sacrificial material layers 42. Thus, each first annular recess region 21 is completely filled with the recess-fill dielectric material layer, while each second annular recess region 23 is only partly filled by the recess-fill dielectric material layer.

A second isotropic etch process can be performed to isotropically etch the material of the recess-fill dielectric material layer. For example, the second isotropic etch process may comprise a wet etch process employing dilute hydrofluoric acid, such as 100:1 dilute hydrofluoric acid. According to an aspect of the present disclosure, the duration of the second isotropic etch process can be selected to ensure removal of the entirety of each portion of the recess-fill dielectric material layer that fills the second annular recess regions 23 of the laterally-expanded contact via cavities 83. In one embodiment, the duration of the second isotropic etch process can be selected such that the recess etch distance of the second isotropic etch process for the material of the recess-fill dielectric material layer is in a range from 105% to 150%, such as from 100% to 130%, of the thickness of the recess-fill dielectric material layer.

The second isotropic etch process removes the recess-fill dielectric material layer from an entire volume of each second annular recess region 23. Thus, the recess-fill dielectric material layer is entirely removed from each second annular recess region 23. Each remaining portion of the recess-fill dielectric material layer that fills a respective one of the first annular recess regions 21 comprises an annular dielectric spacer 26. Thus, each first annular recess region 21 is filled within a respective annular dielectric spacer 26. For each contact via cavity 85 that vertically extends through three or more sacrificial material layers 42, a vertical stack of annular dielectric spacers 26 can be formed around the contact via cavity 85. In other words, for each laterally-expanded contact via cavity 83 that vertically extends through three or more sacrificial material layers 42, a vertical stack of annular dielectric spacers 26 can fill two or more first annular recess regions 21. For each contact via cavity 85 that vertically extends through a plurality of sacrificial material layers 42, each unthickened annular portion of the plurality of sacrificial material layers 42 around the contact via cavity 85 can be replaced with a respective annular dielectric spacer 26. Thus, the annular dielectric spacers 26 are formed within a subset of the annular recess regions (21, 23), i.e., within the first annular recess regions 21.

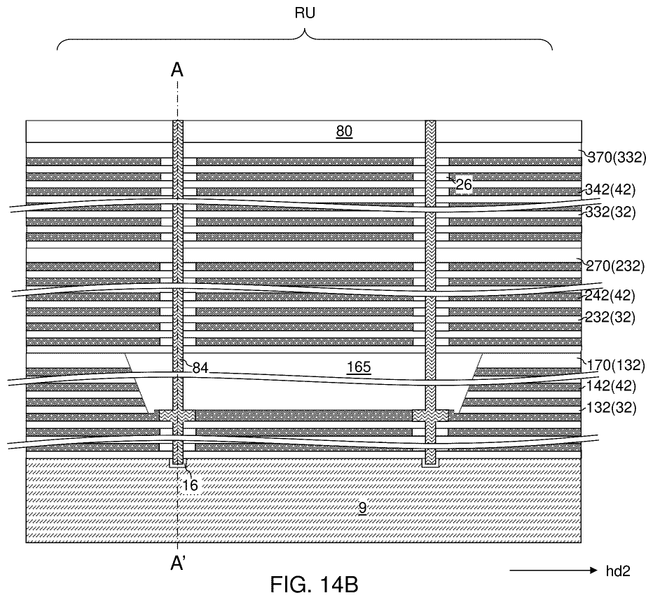

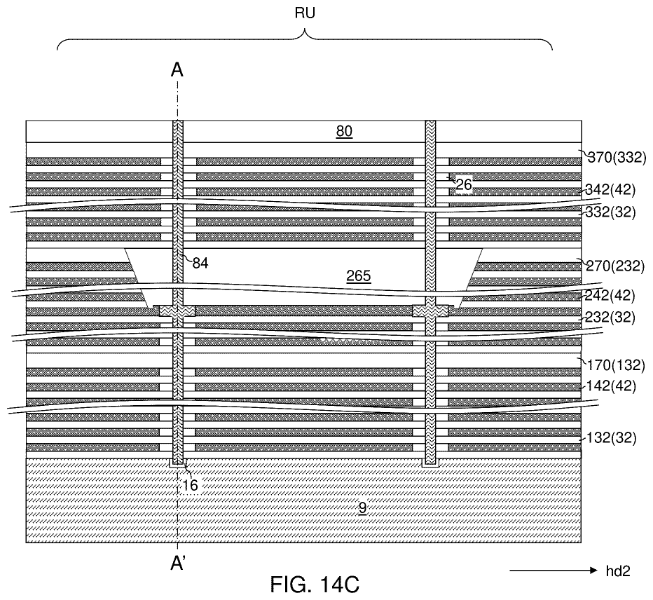

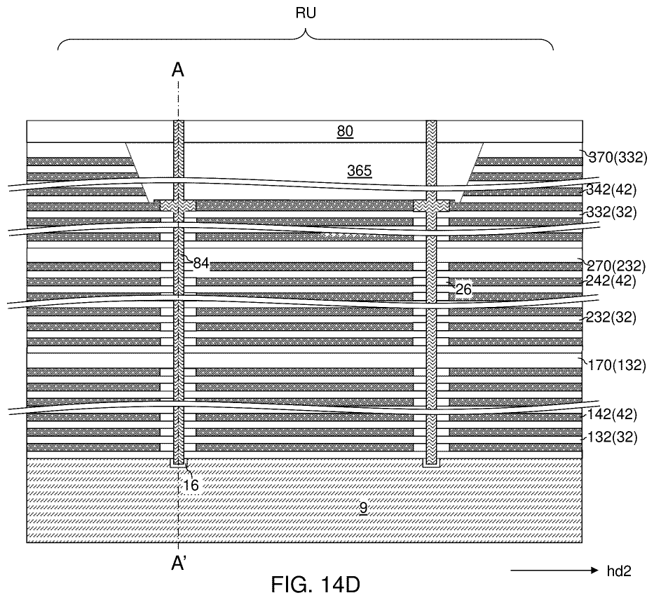

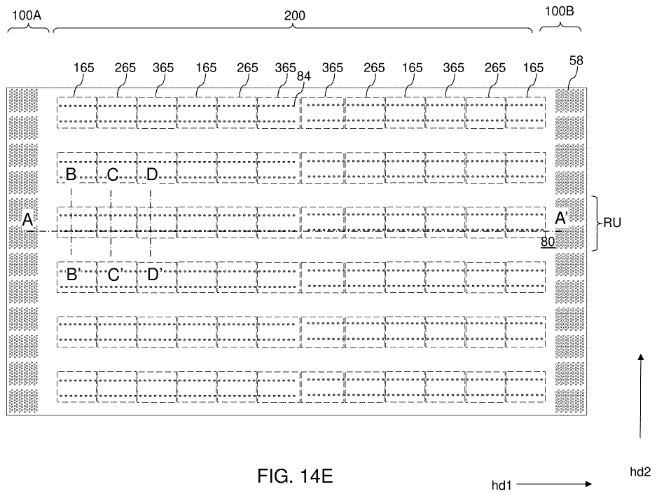

Referring to FIGS. 14A-14E, a sacrificial fill material can be deposited within volumes of the laterally-expanded contact via cavities 83 that are not filled with the annular dielectric spacers 26. The sacrificial fill material may comprise any material that is different from the materials of the insulating layers 32 and the sacrificial material layers 42. For example, the sacrificial fill material may comprise a semiconductor material (e.g., amorphous silicon), organosilicate glass, a polymer material, a photoresist material, or any other sacrificial material that may be subsequently removed selective to materials of the insulating layers 32, the retro-stepped dielectric material portions (165, 265, 365), and electrically conductive layers to be subsequently formed. Excess portions of the sacrificial fill material may be removed from above the horizontal plane including the top surface of the contact-level dielectric layer 80. Each remaining portion of the sacrificial fill material that fills a respective one of the laterally-expanded contact via cavities 83 constitutes a sacrificial through-via structure 84.

Each sacrificial through-via structure 84 is in direct contact with a cylindrical sidewall of a thickened portion of a respective one of the sacrificial material layers 42, and may optionally vertically extend through one or more additional sacrificial material layers 42. Each sacrificial through-via structure 84 is in contact with at least one of the first-tier retro-stepped dielectric material portion 165, the second-tier retro-stepped dielectric material portion 265, and the third-tier retro-stepped dielectric material portion 365. Each sacrificial through-via structure 84 that vertically extends through at least one opening through at least one unthickened portion of the sacrificial material layers 42 is laterally surrounded by, and is contacted by, one or more of the annular dielectric spacers 26. A subset of the sacrificial through-via structures 84 can be laterally surrounded by a respective set of at least one annular dielectric spacer 26. In one embodiment, a subset of the sacrificial through-via structures 84 can be laterally surrounded by a respective vertical stack of annular dielectric spacers 26.

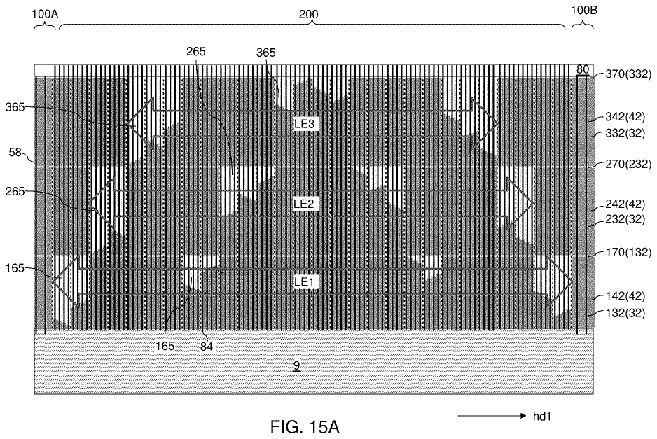

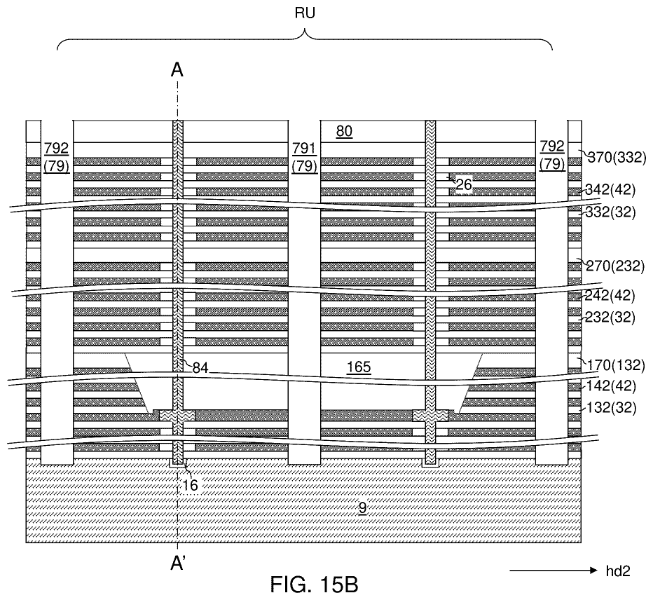

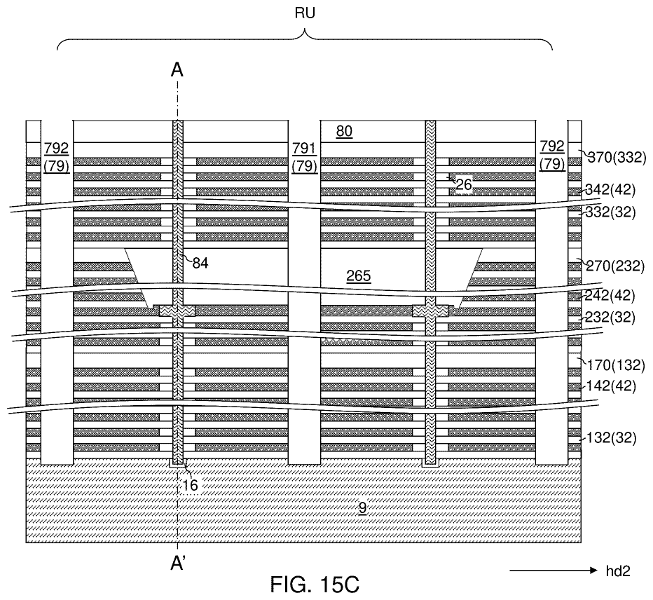

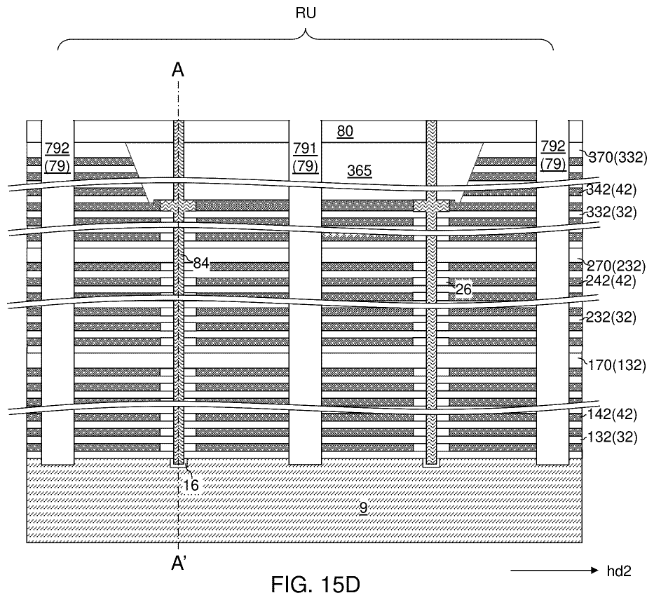

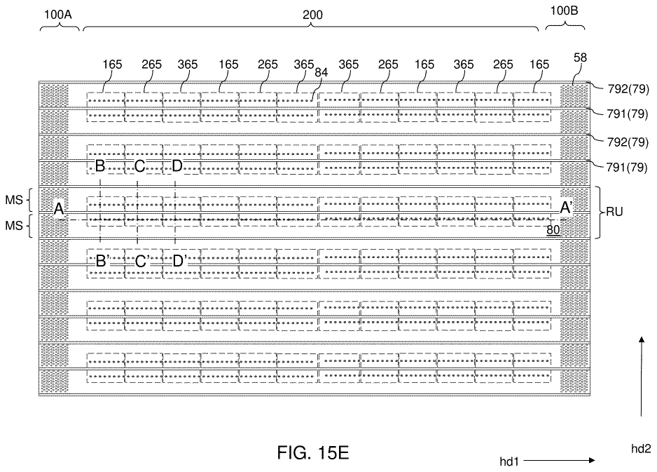

Referring to FIGS. 15A-15E, a patterning film (not shown) can be anisotropically deposited over the contact-level dielectric layer 80. The patterning film comprises a material that may be subsequently employed as an etch mask material. For example, the patterning film may comprise amorphous carbon or diamond-like carbon. The patterning film can be deposited with a highly directional deposition method, such as plasma-enhanced chemical vapor deposition. The patterning film may be subsequently patterned, for example, by applying and lithographically patterning a photoresist layer (not shown). In one embodiment, elongated openings laterally extending along the first horizontal direction hd1 can be formed in the photoresist layer. In one embodiment, the elongated openings may comprise rectangular openings having a uniform width along the second horizontal direction hd2.

In one embodiment, the elongated openings may comprise a one-dimensional array of elongated openings laterally extending along the first horizontal direction hd1, having a uniform width along the second horizontal direction hd2, and having a uniform pitch along the second horizontal direction hd2 that is one half of the periodicity of the repetition unit RU along the second horizontal direction hd2. In one embodiment, each elongated opening may have a uniform width throughout, and may laterally extend through the entirety of the first memory array region 100A, the second memory array region 100B, and the contact region 200. The photoresist layer may be removed after patterning the patterning film, or may be collaterally removed during a subsequent anisotropic etch process that transfers the pattern in the patterning film through the alternating stacks (32, 42) and the retro-stepped dielectric material portions (165, 265, 365).

An anisotropic etch process can be performed to transfer the pattern of the elongated openings in the patterning film through the contact-level dielectric layer 80, the alternating stacks (32, 42), and the retro-stepped dielectric material portions (165, 265, 365). Lateral isolation trenches 79 can be formed in the volumes from which the materials of the contact-level dielectric layer 80, the alternating stacks (32, 42), and the retro-stepped dielectric material portions (165, 265, 365) are removed. In one embodiment, the lateral isolation trenches 79 may comprise first-type lateral isolation trenches 791 that divide a respective row of first-tier retro-stepped dielectric material portion 165, a respective row of second-tier retro-stepped dielectric material portions 265, and a respective row of third-tier retro-stepped dielectric material portions 365, and the respective staircase regions which underlie the respective material portions (165, 265, 365) along the first horizontal direction hd1. Further, the lateral isolation trenches 79 may comprise second-type lateral isolation trenches 792 that do not intersect, and are laterally spaced from, the retro-stepped dielectric material portions (165, 265, 365) and the underlying staircase regions. The patterning film can be subsequently removed, for example, by ashing or selective etching. The lateral isolation trenches 79 are laterally spaced from each of the contact via cavities 85. Optionally, an oxidation process may be performed to convert physically exposed surface portions of the substrate 9 into semiconductor oxide trench liners (not illustrated).

The lateral isolation trenches 79 divide each alternating stack (32, 42) of insulating layers 32 and sacrificial material layers 42 into a respective plurality of alternating stacks (32, 42) of insulating layers 32 and sacrificial material layers 42. For the purpose of distinguishing layers in the first exemplary structure prior to formation of the lateral isolation trenches 79 from layers in the first exemplary structure after formation of the lateral isolation trenches 79, each insulating layer 32 prior to formation of the lateral isolation trenches 79 may be referred to as a continuous insulating layer 32. The continuous insulating layers 32 in the first exemplary structure prior to formation of the lateral isolation trenches 79 may comprise first-tier continuous insulating layers 132, second-tier continuous insulating layers 232, and third-tier continuous insulating layers 332. Likewise, each sacrificial material layer 42 prior to formation of the lateral isolation trenches 79 may be referred to as a continuous sacrificial material layer 42. The continuous sacrificial material layers 42 in the first exemplary structure prior to formation of the lateral isolation trenches 79 may comprise first-tier continuous sacrificial material layers 142, second-tier continuous sacrificial material layers 242, and third-tier continuous sacrificial material layers 342.

Thus, the first-tier alternating stack of first-tier continuous insulating layers 132 and first-tier sacrificial material layers 142 is divided into a plurality of alternating stacks of first-tier insulating layers 132 and first-tier sacrificial material layers 142. The second-tier alternating stack of second-tier continuous insulating layers 232 and second-tier sacrificial material layers 242 is divided into a plurality of alternating stacks of second-tier insulating layers 232 and second-tier sacrificial material layers 242. The third-tier alternating stack of third-tier continuous insulating layers 332 and third-tier sacrificial material layers 342 is divided into a plurality of alternating stacks of third-tier insulating layers 332 and third-tier sacrificial material layers 342.

A vertical stack of a first-tier alternating stack (132, 142), a second-tier alternating stack (232, 242), and a third-tier alternating stack (332, 342) is formed between each neighboring pair of lateral isolation trenches 79. In some cases, the vertical stack may be referred to as an alternating stack of insulating layers 32 and sacrificial material layers 42, in which the distinction among the different tier structures is ignored. Each vertical alternating stack (32, 42) of a first-tier alternating stack (132, 142), a second-tier alternating stack (232, 242), and a third-tier alternating stack (332, 342) embeds a first-tier retro-stepped dielectric material portion 165, a second-tier retro-stepped dielectric material portion 265, and a third-tier retro-stepped dielectric material portion 365. Each first-tier retro-stepped dielectric material portion 165 may comprise a respective lengthwise sidewall that is parallel to the first horizontal direction hd1 and is exposed to a respective first-type lateral isolation trench 791. Each second-tier retro-stepped dielectric material portion 265 may comprise a respective lengthwise sidewall that is parallel to the first horizontal direction hd1 and is exposed to a respective first-type lateral isolation trench 791. Each third-tier retro-stepped dielectric material portion 365 may comprise a respective lengthwise sidewall that is parallel to the first horizontal direction hd1 and is exposed to a respective first-type lateral isolation trench 791. In one embodiment, each retro-stepped dielectric material portion (165, 265, 365) is not in direct contact with any other retro-stepped dielectric material portion (165, 265, 365).

A vertical stack of a first-tier structure, a second-tier structure, and a third-tier structure can be formed between each laterally neighboring pair of lateral isolation trenches 79. The vertical stack of the first-tier structure, the second-tier structure, and the third-tier structure constitutes a multi-tier structure MS, which corresponds to one memory block. The first-tier structure (132, 142, 165) is located over the substrate 9 and comprises a respective first-tier alternating stack (132, 142) of first-tier insulating layers 132 and first-tier sacrificial material layers 142. The second-tier structure (232, 242, 265) overlies the first-tier structure (132, 142, 165) and includes a second-tier alternating stack (232, 242) of second-tier insulating layers 232 and second-tier sacrificial material layers 242. The third-tier structure (332, 342, 365) overlies the second-tier structure (232, 242, 265) and includes a third-tier alternating stack (332, 342) of third-tier insulating layers 332 and third-tier sacrificial material layers 342.

Each multi-tier structure MS embeds a respective set of retro-stepped dielectric material portions (165, 265, 365), which includes first-tier retro-stepped dielectric material portions 165 as a first subset, second-tier retro-stepped dielectric material portions 265 as a second subset, and third-tier retro-stepped dielectric material portions 365 as a third subset. The first-tier alternating stack (132, 142) of each multi-tier structure MS embeds the first subset 165 of the respective set of retro-stepped dielectric material portions (165, 265, 365). The second-tier alternating stack (232, 242) of each multi-tier structure MS embeds the second subset 265 of the respective set of retro-stepped dielectric material portions (165, 265, 365). The third-tier alternating stack (332, 342) of each multi-tier structure MS embeds the third subset 365 of the respective set of retro-stepped dielectric material portions (165, 265, 365).

The first exemplary structure comprises a plurality of multi-tier structures MS located over a growth substrate 9, and laterally spaced apart from each other along the second horizontal direction (e.g., bit line direction) hd2 by a plurality of lateral isolation trenches 79 that laterally extend along a first horizontal direction (e.g., word line direction) hd1. According to an aspect of the present disclosure, within each multi-tier structure MS, at least one subset (165, 265, or 365) of the first subset, the second subset and the third subset of the retro-stepped dielectric material portions comprises three or more retro-stepped dielectric material portions (165, 265, or 365) that are laterally spaced apart from each other along the first horizontal direction hd1. In one embodiment, at least two subsets of the first subset 165, the second subset 265, and the third subset 365 of the retro-stepped dielectric material portions comprise a respective set of three or more retro-stepped dielectric material portions (165, 265, or 365) that are laterally spaced apart from each other along the first horizontal direction hd1. In one embodiment, each subset of the retro-stepped dielectric material portions comprises a respective set of three or more retro-stepped dielectric material portions (165, 265, or 365) that are laterally spaced apart from each other another along the first horizontal direction hd1. In the illustrated example, each subset of the retro-stepped dielectric material portions comprises a respective set of four retro-stepped dielectric material portions (165, 265, or 365) that are laterally spaced apart from each other along the first horizontal direction hd1. Each retro-stepped dielectric material portion (165, 265, 365) does not have any areal overlap with any other retro-stepped dielectric material portion (165, 265, 365) in the first exemplary structure.

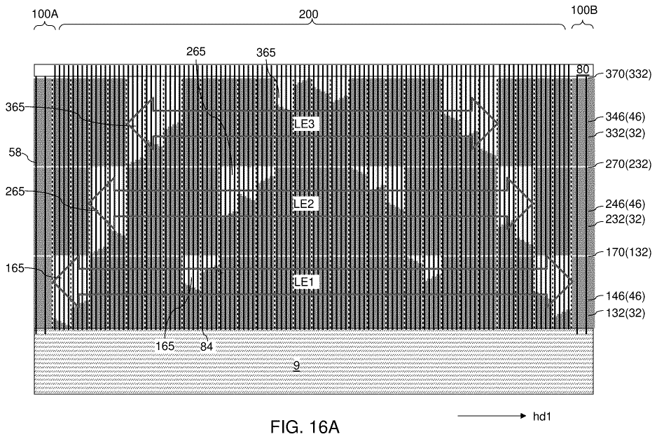

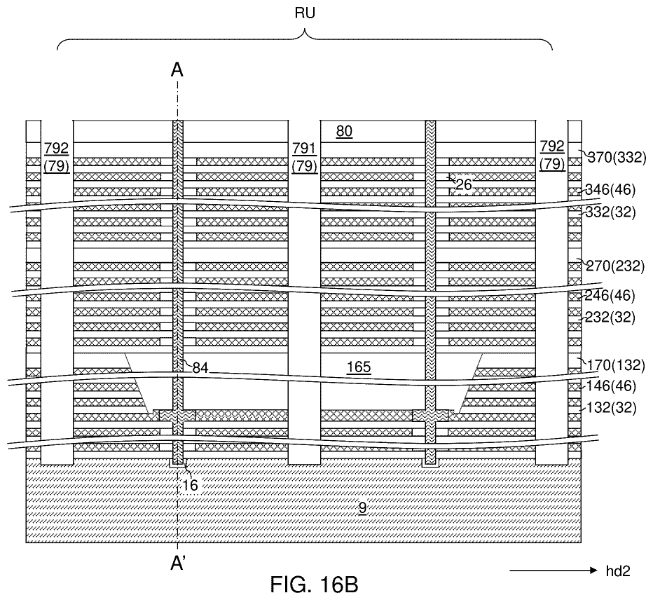

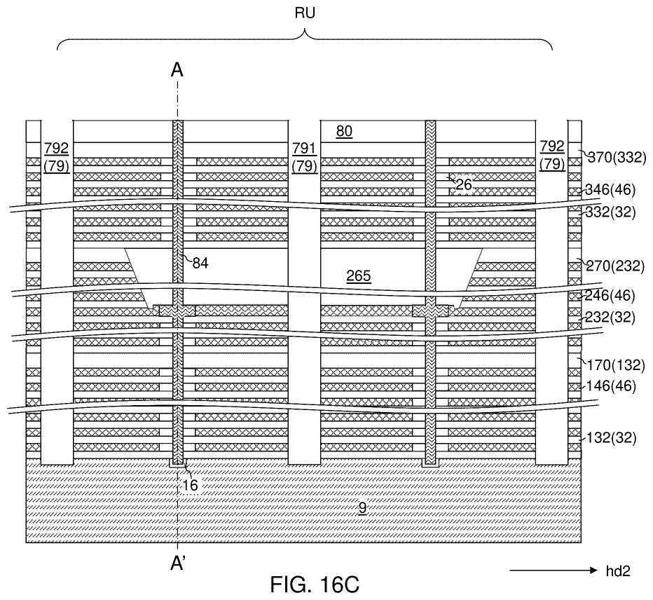

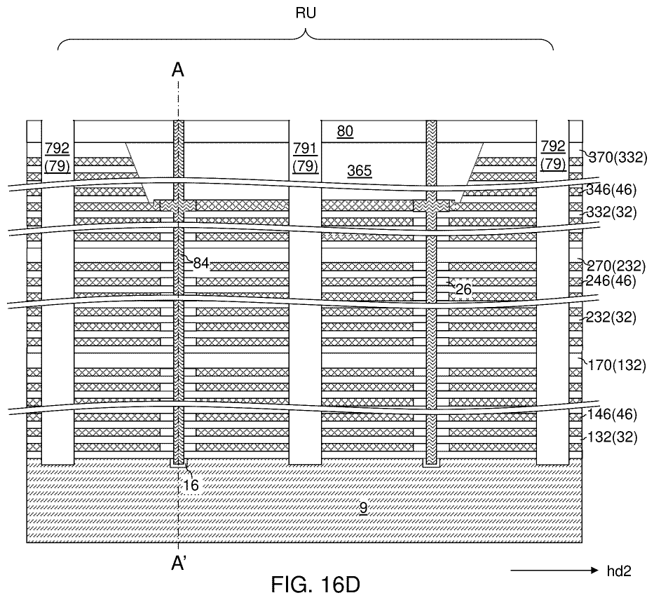

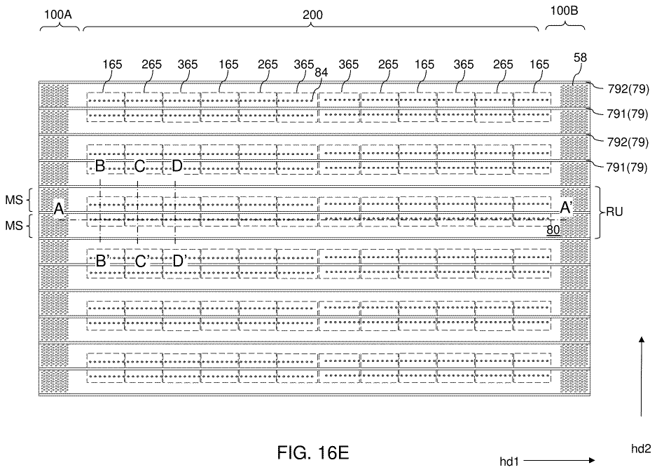

Referring to FIGS. 16A-16E, laterally-extending cavities can be formed by selective removal of the sacrificial material layers 42. A selective etch process can be performed to remove the sacrificial material layers 42 selectively to the insulating layers 32 employing the lateral isolation trenches 79 as conduits for transporting an isotropic etchant of the selective etch process. Specifically, the sacrificial material layers 42 may be isotropically etched selective to the insulating layers 32, the annular dielectric spacers 26, and the retro-stepped dielectric material portions (165, 265, 365) by supplying an isotropic etchant into the lateral isolation trenches 79 and into the contact via cavities 85. In one embodiment, an etchant that selectively etches the materials of the sacrificial material layers 42 with respect to the materials of the insulating layers 32, the annular dielectric spacers 26, the retro-stepped dielectric material portions (165, 265, 365), and the material of the outermost layer of the memory films 50 may be introduced into the lateral isolation trenches, for example, using an isotropic etch process.

The isotropic etch process may be a wet etch process using a wet etch solution, or may be a gas phase (dry) etch process in which the etchant is introduced in a vapor phase into the lateral isolation trench. For example, if the sacrificial material layers 42 comprise silicon nitride, and if the insulating layers 32, the annular dielectric spacers 26, the retro-stepped dielectric material portions (165, 265, 365), and the outermost layer of the memory films 50 comprise silicon oxide materials, the etch process may comprise a hot phosphoric acid etch process, which etches silicon nitride selective to silicon oxide, silicon, and various other materials used in the art.

The laterally-extending cavities are formed in volumes from which the sacrificial material layers 42 are removed. The laterally-extending cavities include first-tier laterally-extending cavities that are formed in volumes from which the first-tier sacrificial material layers 142 are removed, second-tier laterally-extending cavities that are formed in volumes from which the second-tier sacrificial material layers 242 are removed, and third-tier laterally-extending cavities that are formed in volumes from which the third-tier sacrificial material layers 342 are removed. Each of the laterally-extending cavities may be a laterally extending cavity having a greater lateral dimension that is greater than a vertical extent. In other words, the lateral dimension of each of the laterally-extending cavities may be greater than the height of the respective laterally-extending cavity. A plurality of laterally-extending cavities may be formed in the volumes from which the material of the sacrificial material layers 42 is removed. Each of the laterally-extending cavities may extend substantially parallel to the top surface of the substrate 9. A laterally-extending cavity may be vertically bounded by a top surface of an underlying insulating layer 32 and a bottom surface of an overlying insulating layer 32.

An outer blocking dielectric layer (not expressly shown) may be conformally deposited in peripheral portions of the laterally-extending cavities, the contact via cavities 85, and the lateral isolation trenches 79. The outer blocking dielectric layer includes a dielectric material, such as a dielectric metal oxide (e.g., aluminum oxide), silicon oxide, or a combination thereof. The outer blocking dielectric layer may be formed as a continuous material layer having a uniform thickness throughout by a conformal deposition process such as an atomic layer deposition process and/or a chemical vapor deposition process. The thickness of the outer blocking dielectric layer may be in a range from 2 nm to 10 nm, such as from 3 nm to 8 nm, although lesser and greater thicknesses may also be employed.

A continuous electrically conductive material layer (not illustrated) may be deposited over the outer blocking dielectric layer to fill remaining volumes of the laterally-extending cavities, peripheral portions of the lateral isolation trenches 79, and peripheral portions of the contact via cavities 85. The lateral isolation trenches 79 are used conduits for transporting the reactants (e.g., CVD or ALD reactants) to the volumes of the laterally-extending cavities. In one embodiment, the continuous electrically conductive material layer may comprise a continuous metallic barrier liner layer (not expressly shown) and a continuous metal fill material layer (not expressly shown).

Specifically, a continuous metallic barrier liner layer may be conformally deposited on the physically exposed surfaces of the outer blocking dielectric layer in peripheral portions of the laterally-extending cavities and the lateral isolation trenches 79. The continuous metallic barrier liner layer comprises a metallic diffusion barrier material. For example, the continuous metallic barrier liner layer may comprise and/or may consist essentially of a conductive metal nitride material, such as TiN, TaN, WN, and/or MoN. The continuous metallic barrier liner layer may be formed as a continuous material layer having a uniform thickness throughout by a conformal deposition process such as an atomic layer deposition process and/or a chemical vapor deposition process. The thickness of the continuous metallic barrier liner layer may be in a range from 1.5 nm to 8 nm, such as from 3 nm to 6 nm, although lesser and greater thicknesses may also be employed. In one embodiment, the continuous metallic barrier liner layer extends continuously over the entirety of the outer blocking dielectric layer as a single continuous material layer.

The continuous metal fill material layer may be conformally deposited on the physically exposed surfaces of the continuous metallic barrier liner layer in remaining unfilled volumes of the laterally-extending cavities and in peripheral regions of the lateral isolation trenches 79. The continuous metal fill material layer comprises a metal fill material that provides high electrical conductivity. For example, the continuous metal fill material layer comprises and/or consists essentially of an elemental metal such as W, Co, Ru, Mo, Cu, or a combination thereof. The continuous metal fill material layer may be formed by a conformal deposition process, such as a chemical vapor deposition (CVD) process or an atomic layer deposition (ALD) process. The lateral isolation trenches 79 may be used as conduits for the reactant that deposits the continuous metal fill material layer. In one embodiment, the continuous metal fill material layer extends continuously over the entirety of the continuous metallic barrier liner layer as a single continuous material layer.

The combination of the outer blocking dielectric layer, the continuous metallic barrier liner layer, and the continuous metal fill material layer fill the entirety of the laterally-extending cavities, and fill peripheral portions of the lateral isolation trenches 79. Generally, at least one conformal deposition process can be performed after formation of the outer blocking dielectric layer to deposit at least one first electrically conductive material of the electrically conductive material layer in remaining volumes of the laterally-extending cavities, and in an elongated tubular regions of each lateral isolation trench 79. Each portion of the continuous electrically conductive material layer that replaces an unthickened portion of the sacrificial material layers 42 may have a first thickness, and each portion of the continuous electrically conductive material layer that replace a thickened portion of the sacrificial material layers 42 may have a second thickness which is greater than the first thickness.

A selective etch process can be performed to etch portions of the continuous electrically conductive material layer from inside the lateral isolation trenches 79. Each remaining portion of the combination of the continuous metallic barrier liner layer and the continuous metal fill material layer that fills a respective laterally-extending cavity constitutes an electrically conductive layer 46. The electrically conductive layers 46 comprise first-tier electrically conductive layers 146 that are formed in the first-tier laterally-extending cavities, second-tier electrically conductive layers 246 that are formed in the second-tier laterally-extending cavities, and third-tier electrically conductive layers 346 that are formed in the third-tier laterally-extending cavities. First-tier alternating stacks (132, 246) of first-tier insulating layers 132 and first-tier electrically conductive layers 146 are formed within the first-tier structure, second-tier alternating stacks (132, 246) of second-tier insulating layers 232 and second-tier electrically conductive layers 246 are formed within the second-tier structure, and third-tier alternating stacks (132, 246) of third-tier insulating layers 332 and third-tier electrically conductive layers 346 are formed within the third-tier structure.

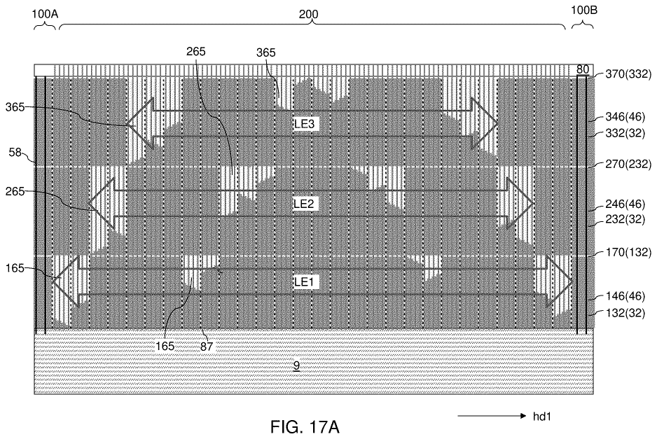

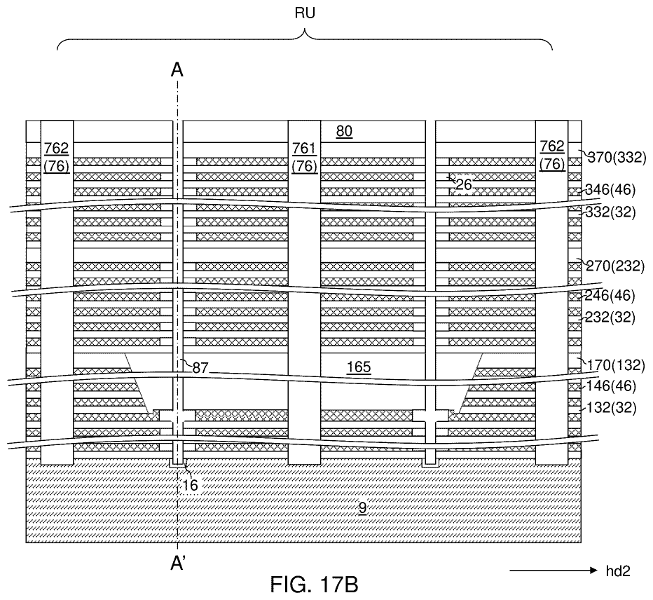

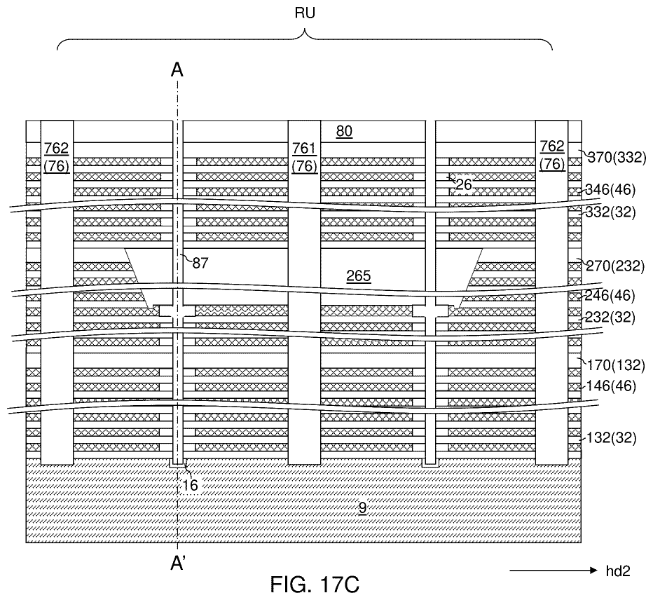

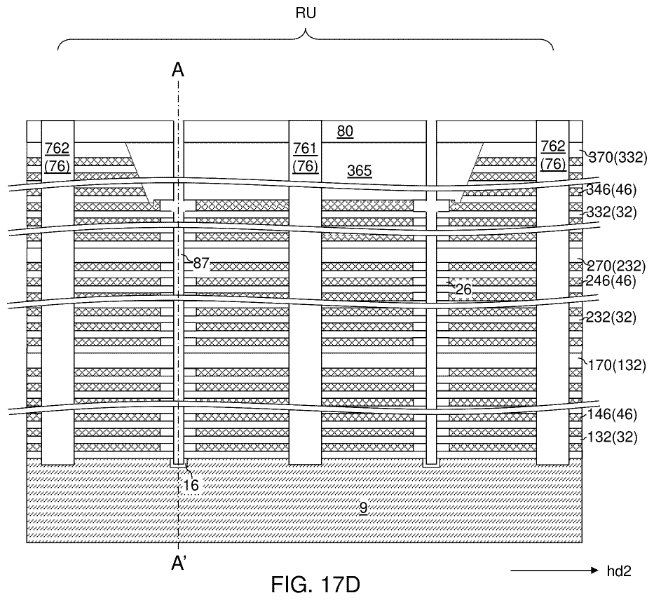

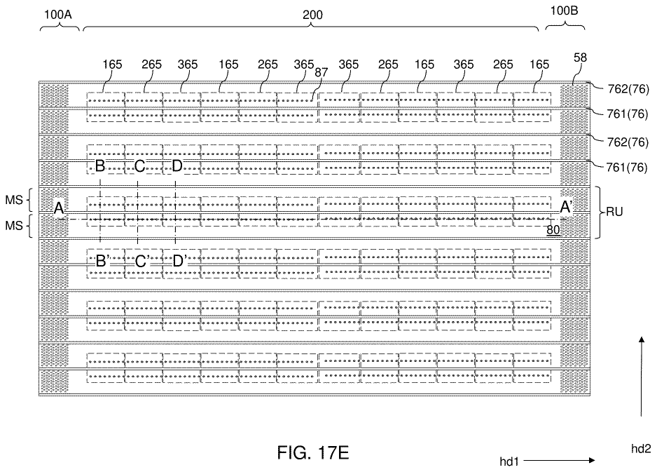

Referring to FIGS. 17A-17E, a dielectric fill material, such as undoped silicate glass or a doped silicate glass, can be deposited in the lateral isolation trenches 79 by a conformal deposition process. Excess portions of the dielectric fill material may be removed from above the horizontal plane including the top surface of the contact-level dielectric layer 80 by a planarization process, which may comprise a recess etch process and/or a chemical mechanical polishing process. Each remaining portion of the dielectric fill material that fills a respective one of the lateral isolation trenches 79 constitute a lateral isolation trench fill structure 76. The lateral isolation trench fill structures 76 may comprise first-type lateral isolation trench fill structures 761 that are formed in the first-type lateral isolation trenches 791 and second-type lateral isolation trench fill structures 762 that are formed in the second-type lateral isolation trenches 792.

A plurality of lateral isolation trench fill structures 76 can be formed in the plurality of lateral isolation trenches 79. Each multi-tier structure MS within the plurality of multi-tier structures MS comprises a first lengthwise sidewall that is parallel to the first horizontal direction hd1 and contacting a respective one of the lateral isolation trench fill structures 76 and a second lengthwise sidewall that is parallel to the first horizontal direction hd1 and contacting a respective additional one of the lateral isolation trench fill structures 76.

A selective etch process may be performed to remove sacrificial through-via structures 84 selective to the materials of the contact-level dielectric layer 80, the retro-stepped dielectric material portions (165, 265, 365), the insulating layers 32, and the electrically conductive layers 46. Through-via cavities 87 can be formed in the volumes from which the sacrificial through-via structures 84 are removed. An isotropic etch process may be performed to remove any physically exposed portion of the outer blocking dielectric layers (not shown) from around the through-via cavities 87. Each through-via cavity 87 is a contact via cavity to which a surface of a respective electrically conductive layer 46 is physically exposed. In one embodiment, each through-via cavity 87 comprises a respective annular recess region to which a cylindrical sidewall of a respective electrically conductive layer 46 is physically exposed.

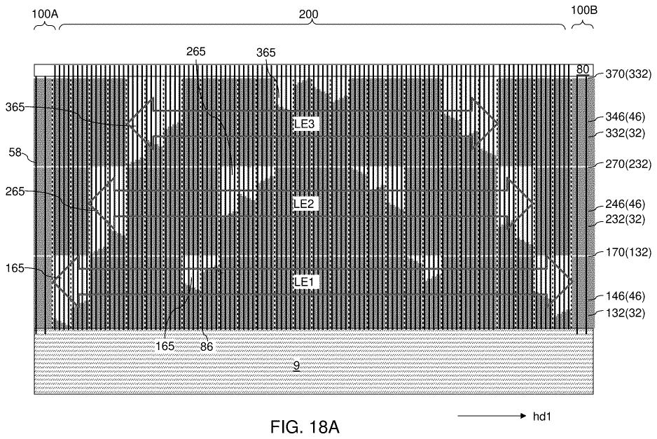

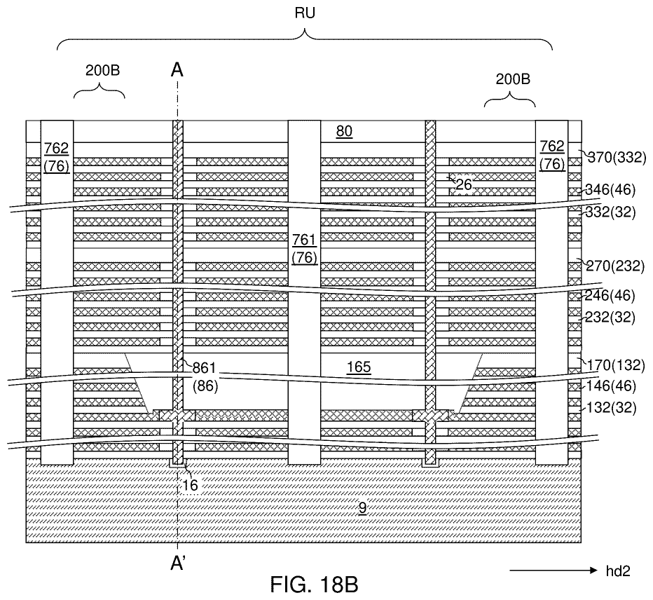

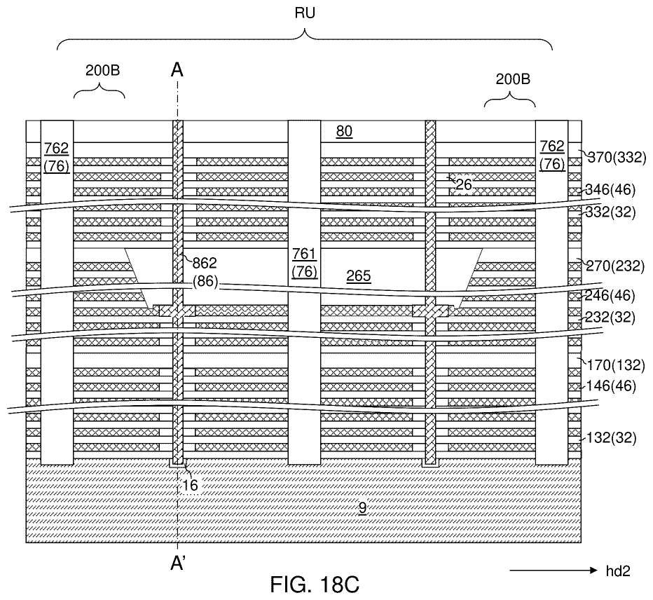

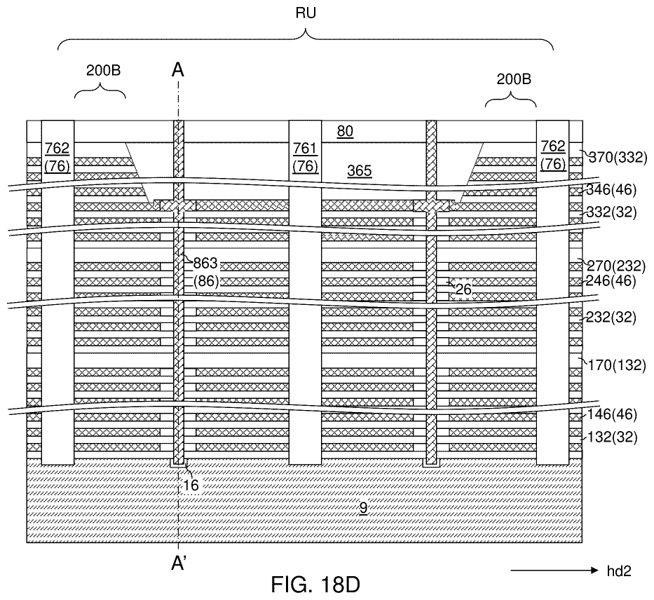

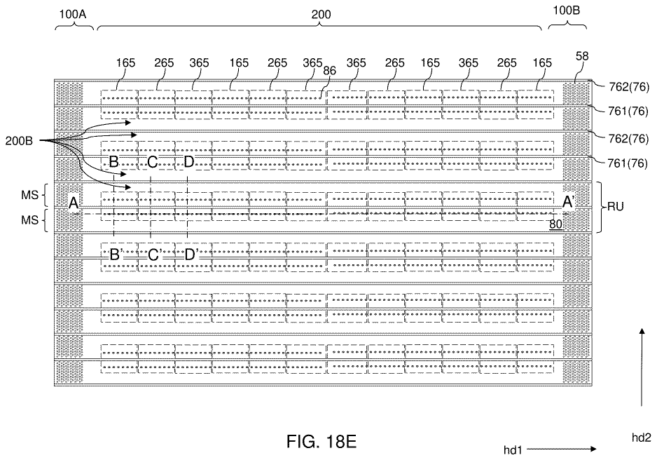

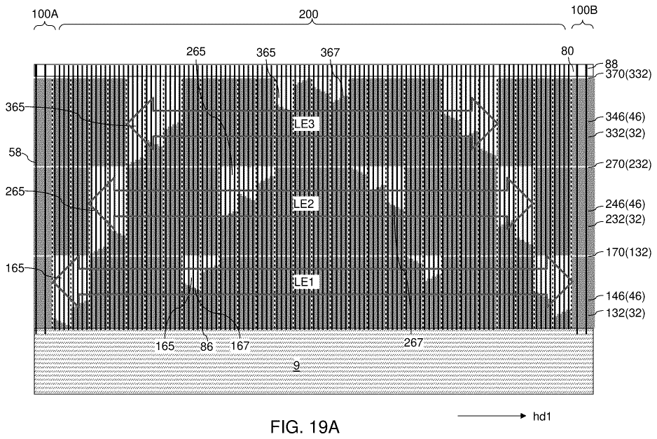

Referring to FIGS. 18A-18E, at least one electrically conductive material, such as a combination of a metallic barrier liner material and a metal fill material, can be conformally deposited in the through-via cavities 87 directly on physically exposed surface segments of the electrically conductive layers 46. Excess portions of the at least one electrically conductive material may be removed from above the horizontal plane including the top surface of the contact-level dielectric layer 80 by a planarization process, which may comprise a recess etch process and/or a chemical mechanical polishing process. Each remaining portion of the at least one electrically conductive material filling a respective one of the through-via cavities 87 constitute a through-via contact structure 86. The through-via contact structures 86 comprise first-tier-contact through-via contact structures 861 that contact a respective one of the first-tier electrically conductive layers 461, second-tier-contact through-via contact structures 862 that contact a respective one of the second-tier electrically conductive layers 462, and third-tier-contact through-via contact structures 863 that contact a respective one of the third-tier electrically conductive layers 463.

Each through-via contact structure 86 vertically extends through a respective retro-stepped dielectric material portion (165, 265, or 365) and a set of at least one electrically conductive layer 46 located within a same tier structure as the respective retro-stepped dielectric material portion (165, 265, or 365) and underlies the respective retro-stepped dielectric material portion (165, 265, or 365). Each through-via contact structure 86 is electrically connected to, and is in direct contact with, a topmost electrically conductive layer 46 within the set of at least one electrically conductive layer 46. If the set of at least one electrically conductive layer 46 comprises a plurality of electrically conductive layers 46, the through-via contact structure 86 is laterally spaced from, and is electrically isolated from, each electrically conductive layer 46 within the set except the topmost electrically conductive layer 46 within the set by at least one annular dielectric spacer 26. In case the through-via contact structure 86 vertically extends through any opening in any other electrically conductive layer 46 that overlies the tier structure or underlies the tier structure, the through-via contact structure 86 is laterally spaced from, and is electrically isolated from, any such electrically conductive layer 46 by a respective annular dielectric spacer 26.

In one embodiment, each of the first-tier, second-tier and third-tier electrically conductive layers (146, 246, 346) continuously extends from the first memory array region 100A to the second memory array region 100B through a bridge portion 200B of the contact region 200. The bridge portion 200B of the contact region 200 is laterally offset from the set of retro-stepped dielectric material portions (165, 265, 365) along a second horizontal direction hd2 which is perpendicular to the first horizontal direction hd1.

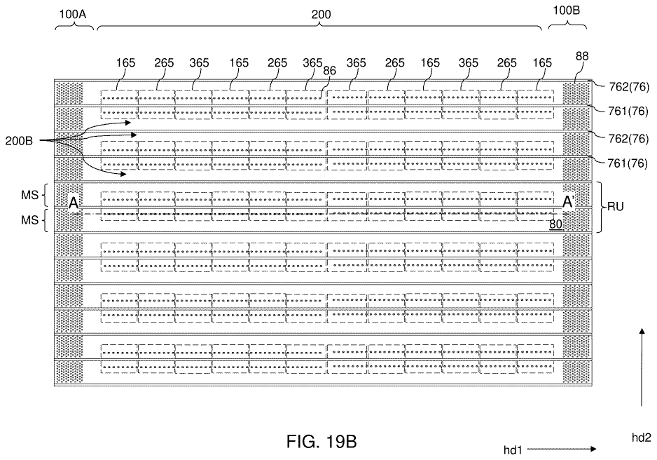

Referring to FIGS. 19A and 19B, drain contact via structures 88 can be formed through the contact-level dielectric layer 80 on the drain regions 63 within the memory opening fill structures 58. Each drain region 63 may be contacted by a respective one of the drain contact via structures 88.

Subsequently, additional dielectric material layers and additional metal interconnect structures can be formed over the contact-level dielectric layer 80. The first exemplary structure includes a two-dimensional array of memory dies. The first exemplary structure may be bonded to another substrate supporting a respective two-dimensional array of semiconductor dies, which may comprise logic dies or additional memory dies. A dicing process may be subsequently performed. Alternatively, the two-dimensional array of memory dies may be diced without bonding to another wafer.

In summary, each of the multi-tier structures MS comprises a respective set of through-via contact structures 86 vertically extending between a horizontal plane including a top surface of a topmost layer of the third-tier alternating stack (332, 346) and a horizontal plane including a bottom surface of a bottommost layer of the first-tier alternating stack (132, 146) and electrically connected to a single electrically conductive layer 46 among the first-tier electrically conductive layers 146, the second-tier electrically conductive layers 246, and the third-tier electrically conductive layers 346.

The multi-tier structure MS further comprises staircase regions (167, 267, 367) underlying the set of retro-stepped dielectric material portions (165, 265, 365). First-tier staircase regions 167 underlie the first-tier retro-stepped dielectric material portions 165, second-tier staircase regions 267 underlie the second-tier retro-stepped dielectric material portions 265, and third-tier staircase regions 367 underlie the third-tier retro-stepped dielectric material portions 365. The staircase regions are located in the contact region and comprise horizontally extending portions of the electrically conductive layers 46 contacting the respective through-via contact structures 86.

In one embodiment, within each multi-tier structure MS, the respective set of through-via contact structures 86 comprises first through-via contact structures 861 vertically extending through each of the second-tier electrically conductive layers 246 and the third-tier electrically conductive layers 346 and electrically connected to a respective one of the first-tier electrically conductive layers 146. In one embodiment, within each multi-tier structure MS, each of the first through-via contact structures 861 is electrically isolated from each of the second-tier electrically conductive layers 246 and the third-tier electrically conductive layers 346 by annular dielectric spacers 26 that are located within openings through the second-tier electrically conductive layers 246 and the third-tier electrically conductive layers 346.

In one embodiment, within each multi-tier structure MS, the respective set of through-via contact structures 86 also comprises second through-via contact structures 862 vertically extending through each of the first-tier electrically conductive layers 146 and the third-tier electrically conductive layers 346 and electrically connected to a respective one of the second-tier electrically conductive layers 246. In one embodiment, within each multi-tier structure MS, each of the second through-via contact structures 862 is electrically isolated from each of the first-tier electrically conductive layers 146 and the third-tier electrically conductive layers 346 by annular dielectric spacers 26 that are located within openings through the first-tier electrically conductive layers 146 and the third-tier electrically conductive layers 346. In one embodiment, within each multi-tier structure MS, each through-via contact structure 86 within the respective set of through-via contact structures 86 vertically extends through no more than one retro-stepped dielectric material portion (165, 265, or 365) within the respective set of retro-stepped dielectric material portions (165, 265, 365).

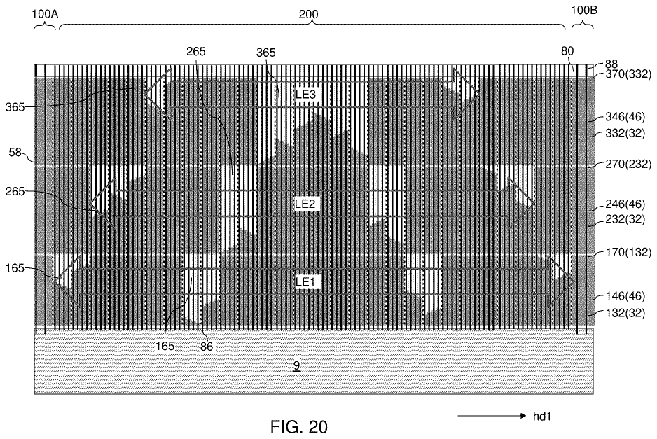

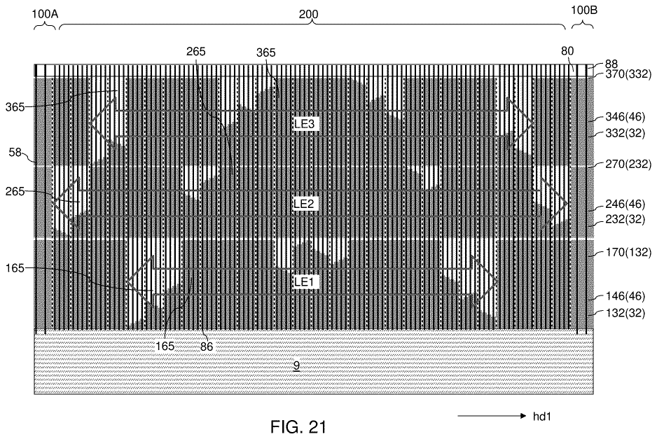

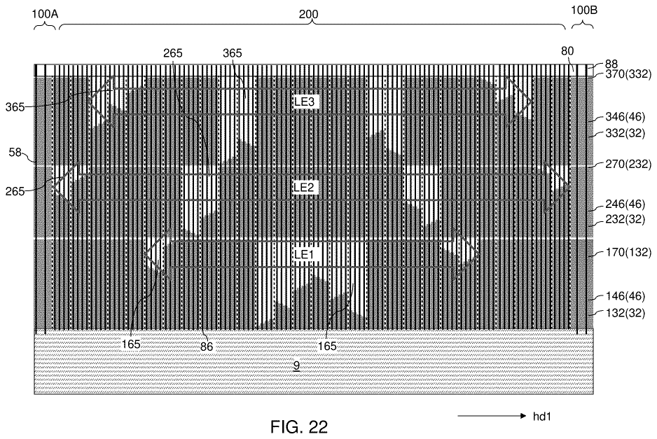

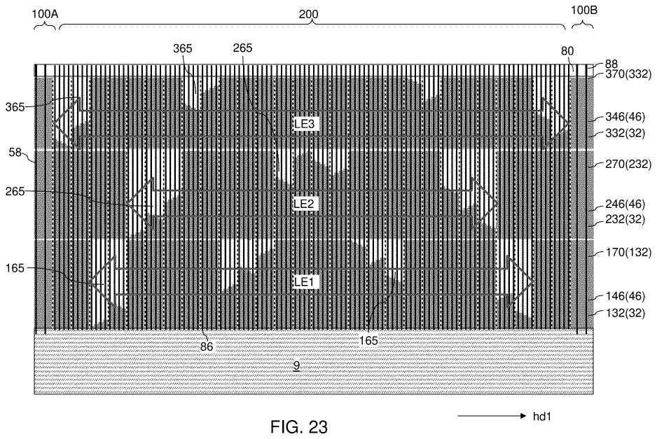

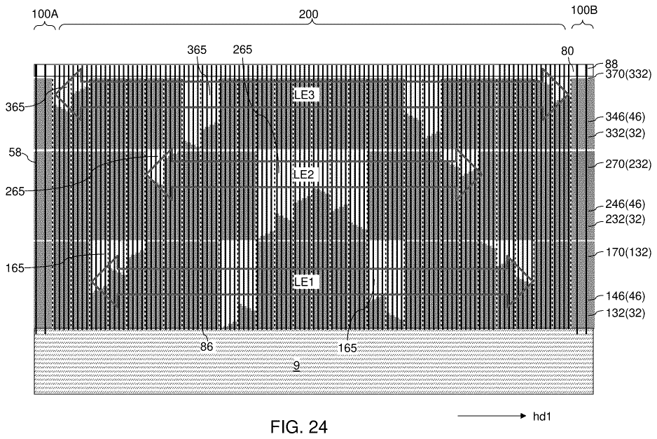

Referring to FIGS. 20, 21, 22, 23, and 24, a second exemplary structure, a third exemplary structure, a fourth exemplary structure, a fifth exemplary structure, and a sixth exemplary structure are illustrated, respectively. Each of the second exemplary structure, the third exemplary structure, the fourth exemplary structure, the fifth exemplary structure, and the sixth exemplary structure may be derived from the first exemplary structure by rearranging the pattern for the first-tier retro-stepped dielectric material portions 165, the pattern for the second-tier retro-stepped dielectric material portions 265, and the pattern for the third-tier retro-stepped dielectric material portions 365 (as well as the underlying staircase region) from each other. Accordingly, the relative magnitudes among the lateral extents (LE1, LE2, LE3) for the retro-stepped dielectric material portions (165, 265, 365) may be different among the first through sixth exemplary structures. In the second exemplary structure shown in FIG. 20, the deeper recesses overlying the staircase steps are moved further away from the memory array regions (100A, 100B) towards the middle of the contact region 200 than in the first exemplary structure shown in FIG. 19A. Furthermore, the shallower recesses of the second exemplary structure are moved closer to the memory array regions than in the first exemplary structure. This reduces the chance of multi-tier structure MS tilting and collapse into the lateral isolation trenches 79 during device fabrication.

Generally, within each multi-tier structure MS, the first subset of the retro-stepped dielectric material portions 165 has a first lateral extent LE1 which is a maximum lateral spacing along the first horizontal direction hd1 of sidewalls of the first subset 165 that are perpendicular to the first horizontal direction hd1, the second subset of the retro-stepped dielectric material portions 265 has a second lateral extent LE2 which is a maximum lateral spacing along the first horizontal direction hd1 of sidewalls of the second subset 265 that are perpendicular to the first horizontal direction hd1, and the third subset of the retro-stepped dielectric material portions 365 has a third lateral extent LE3 which is a maximum lateral spacing along the first horizontal direction hd1 of sidewalls of the third subset 365 that are perpendicular to the first horizontal direction hd1. The second lateral extent LE2 is different from the first lateral extent LE1, and may be greater than or less than the first lateral extent LE1. The third lateral extent LE3 is different from the first lateral extent LE1, and may be greater than or less than the first lateral extent LE1. The third lateral extent LE3 is different from the second lateral extent LE2, and may be greater than or less than the second lateral extent LE2.

The total number of retro-stepped dielectric material portions (165, 265, or 365) and respective underlying staircase regions within each tier structure may be 2, 3, 4 or more. In the first through sixth exemplary structures, the total number of retro-stepped dielectric material portions (165, 265, or 365) and the respective underlying staircase regions within each tier structure is 4.

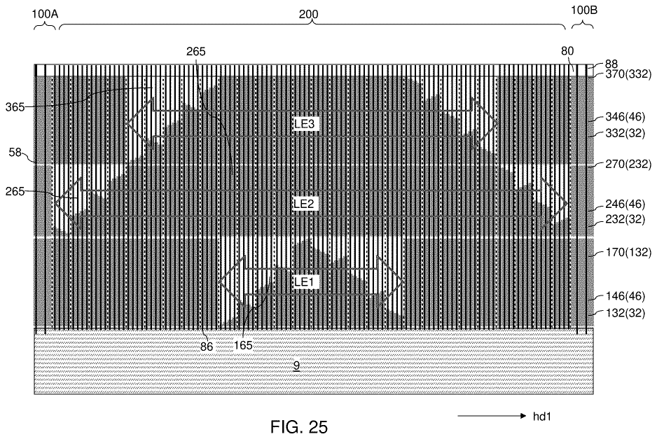

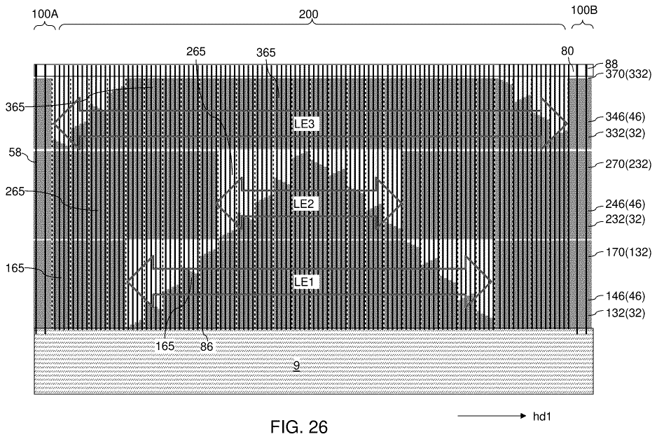

Referring to FIGS. 25 and 26, the various exemplary structures may be modified such that the total number of retro-stepped dielectric material portions (165, 265, or 365) and the respective underlying staircase regions within one or more of the tier structures is not 4. Generally, the total number of retro-stepped dielectric material portions (165, 265, or 365) within each tier structure may be in a range from 1 to 16, such as from 2 to 6, for example from 3 to 4. FIG. 25 illustrates a seventh exemplary structure in which the total number of retro-stepped dielectric material portions (165, 265, or 365) within each tier structure is 2, the second lateral extent LE2 is greater than the third lateral extent LE3, and the third lateral extent LE3 is greater than the first lateral extent LE1. FIG. 26 illustrates an eighth exemplary structure in which the total number of retro-stepped dielectric material portions (165, 265, or 365) within each tier structure is 2, the third lateral extent LE3 is greater than the first lateral extent LE1, and the first lateral extent LE1 is greater than the second lateral extent LE2.

Referring collectively to FIGS. 1-26 and according to various embodiments of the present disclosure, a device structure comprises a multi-tier structure MS comprising a first-tier structure (132, 146, 165) including a first-tier alternating stack (132, 146) of first-tier insulating layers 132 and first-tier electrically conductive layers 146, a second-tier structure (232, 246, 265) overlying the first-tier structure (132, 146, 165) and including a second-tier alternating stack (232, 246) of second-tier insulating layers 232 and second-tier electrically conductive layers 246, and a third-tier structure (332, 346, 365) overlying the second-tier structure (232, 246, 265) and including a third-tier alternating stack (332, 346) of third-tier insulating layers 332 and third-tier electrically conductive layers 346. A first memory array region 100A comprises a plurality of first memory opening fill structures 58 vertically extending through the multi-tier structure MS. A second memory array region 100B comprises a plurality of second memory opening fill structures 58 vertically extending through the multi-tier structure MS. The second memory array region 100B is laterally offset from the first memory array region 100A along a first horizontal direction hd1 by a contact region 200 of the multi-tier structure MS. A set of retro-stepped dielectric material portions (165, 265, 365) is embedded in the contact region 200. The first-tier alternating stack (132, 146) embeds a first subset 165 of the respective set of retro-stepped dielectric material portions (165, 265, 365), the second-tier alternating stack (232, 246) embeds a second subset 265 of the respective set of retro-stepped dielectric material portions (165, 265, 365), and the third-tier alternating stack (332, 346) embeds a third subset 365 of the respective set of retro-stepped dielectric material portions (165, 265, 365). At least one subset among the first subset, the second subset, or the third subset of the retro-stepped dielectric material portions (165, 265, 365) comprises three or more retro-stepped dielectric material portions (165, 265, or 365) that are laterally spaced apart from each other along the first horizontal direction hd1.

In one embodiment, the multi-tier structure MS further comprises staircase regions (167, 267, 367) underlying the set of retro-stepped dielectric material portions (165, 265, 365), and a plurality of through-via contact structures 86 vertically extending between a horizontal plane including a top surface of a topmost layer of the third-tier alternating stack (332, 346) and a horizontal plane including a bottom surface of a bottommost layer of the first-tier alternating stack (132, 146) and electrically connected to a single electrically conductive layer 46 of the first-tier electrically conductive layers 146, the second-tier electrically conductive layers 246, and the third-tier electrically conductive layers 346 in a respective one of the staircase regions (167, 267, 367).

In one embodiment, the plurality of the through-via contact structures 86 comprise first through-via contact structures 861 vertically extending through each of the second-tier electrically conductive layers 246 and the third-tier electrically conductive layers 346 and electrically connected to a respective one of the first-tier electrically conductive layers 146; second through-via contact structures 862 vertically extending through each of the first-tier electrically conductive layers and the third-tier electrically conductive layers and electrically connected to a respective one of the second-tier electrically conductive layers 246; and third through-via contact structures 863 vertically extending through each of the first-tier electrically conductive layers and the second-tier electrically conductive layers and electrically connected to a respective one of the third-tier electrically conductive layers 346.

In one embodiment, each of the first through-via contact structures 861 is electrically isolated from each of the second-tier electrically conductive layers 246 and the third-tier electrically conductive layers 346 by annular dielectric spacers 26 that are located within openings through the second-tier electrically conductive layers 246 and the third-tier electrically conductive layers 346; each of the second through-via contact structures 862 is electrically isolated from each of the first-tier electrically conductive layers 146 and the third-tier electrically conductive layers 346 by annular dielectric spacers 26 that are located within openings through the first-tier electrically conductive layers 146 and the third-tier electrically conductive layers; and each of the third through-via contact structures 863 is electrically isolated from each of the first-tier electrically conductive layers 146 and the second-tier electrically conductive layers 246 by annular dielectric spacers 26 that are located within openings through the first-tier electrically conductive layers 146 and the second-tier electrically conductive layers 246.

In one embodiment, each of the first and second memory opening fill structures comprises 58 a respective first semiconductor channel 60 and a respective first memory film 50. In one embodiment, each of the first-tier, second-tier and third-tier electrically conductive layers (146, 246, 346) continuously extends from the first memory array region 100A to the second memory array region 100B through a bridge portion 200B of the contact region 200. The bridge portion 200B of the contact region 200 is laterally offset from the set of retro-stepped dielectric material portions (165, 265, 365) along a second horizontal direction hd2 which is perpendicular to the first horizontal direction hd1. In one embodiment, each of the retro-stepped dielectric material portions within the respective set of retro-stepped dielectric material portions (165, 265, 365) overlies least one ascending staircase portion and at least one descending staircase portion of a respective staircase region (167, 267, 367).

In one embodiment, each through-via contact structure 86 vertically extends through no more than one retro-stepped dielectric material portion (165, 265, or 365) within the respective set of retro-stepped dielectric material portions (165, 265, 365).

In one embodiment, at least two subsets of the first subset, the second subset, and the third subset of retro-stepped dielectric material portions (165, 265, 365) comprises three or more retro-stepped dielectric material portions (165, 265, or 365) that are laterally spaced apart from each other along the first horizontal direction hd1. In one embodiment, each subset comprises three or more retro-stepped dielectric material portions (165, 265, or 365) that are laterally spaced apart from each other along the first horizontal direction hd1. In one embodiment, the at least one subset comprises four retro-stepped dielectric material portions (165, 265, 365) that are laterally spaced apart from each other along the first horizontal direction hd1.

In one embodiment, the device also includes a second multi-tier structure which is laterally spaced from the multi-tier structure MS along the second horizontal direction hd2 by a lateral isolation trench 79 which extends in the first horizontal direction hd1, and a lateral isolation trench fill structure 76 is located in the lateral isolation trench 79.

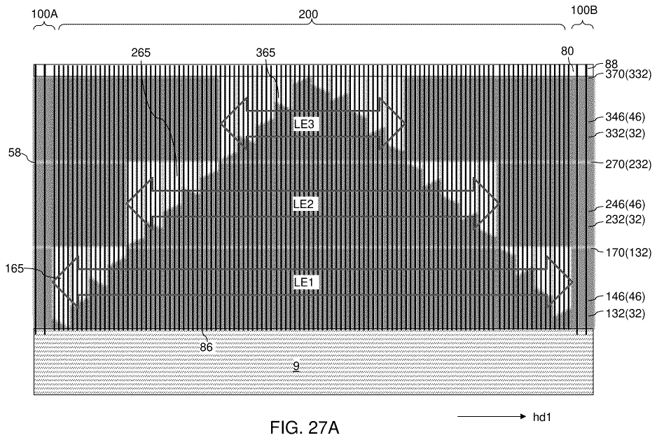

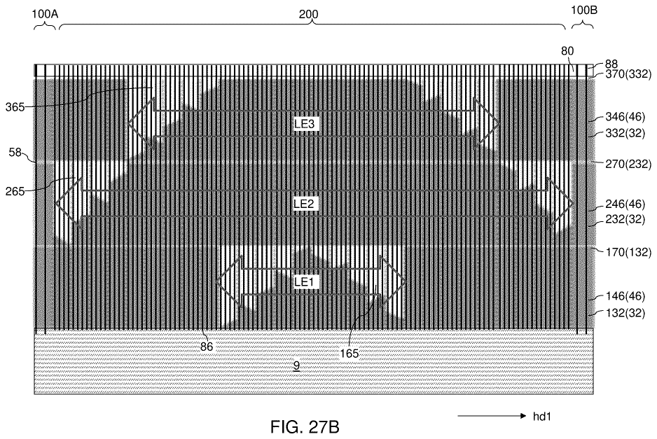

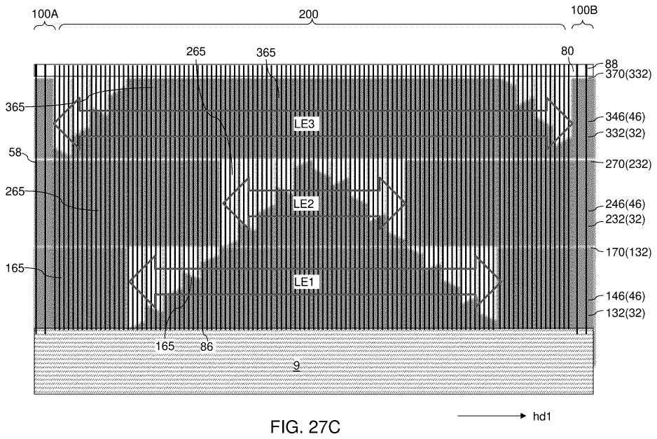

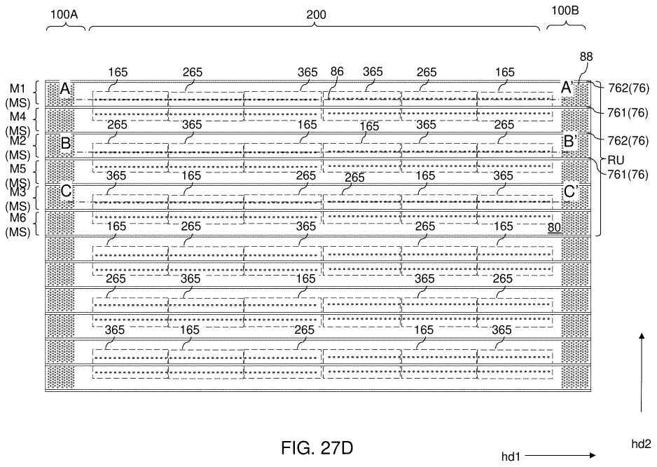

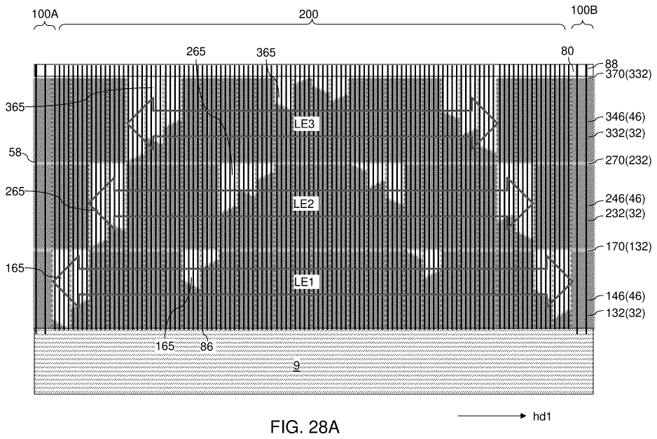

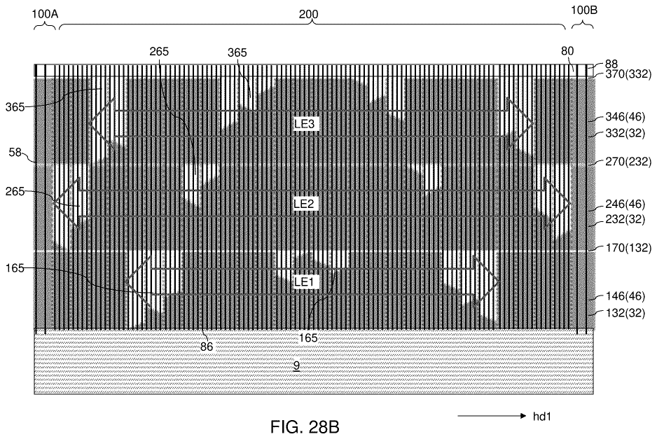

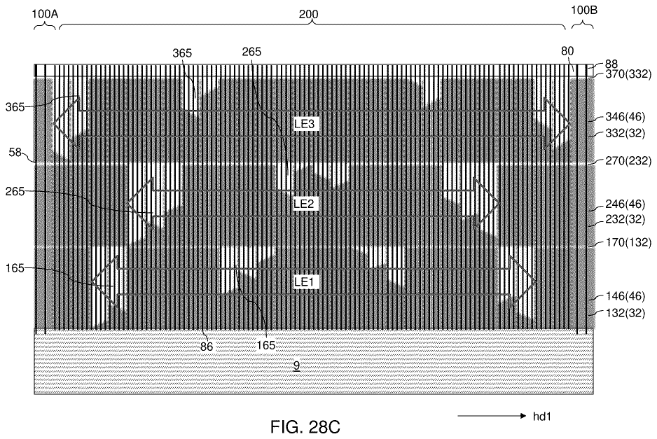

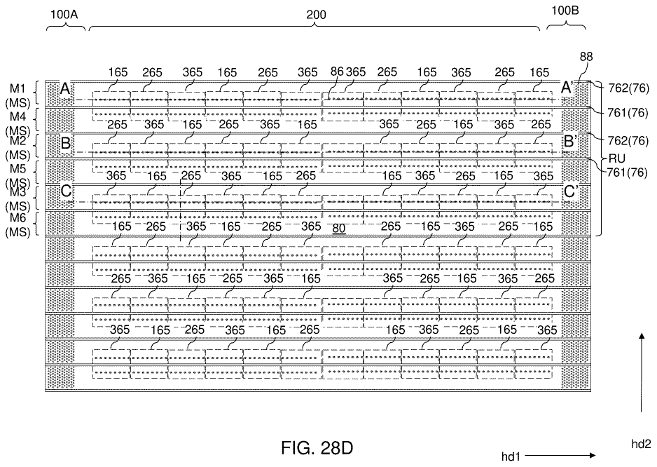

According to another embodiment of the present disclosure, the patterns of the retro-stepped dielectric material portions (165, 265, 365) may be different among the multi-tier structures MS. For example, a repetition unit RU within a device structure may comprise, from one side to another along the second horizontal direction hd2, a first multi-tier structure M1, a fourth multi-tier structure M4, a second multi-tier structure M2, a fifth multi-tier structure M5, a third multi-tier structure M3, and a sixth multi-tier structure M6 as illustrated in a ninth exemplary structure shown in FIGS. 27A-27D or as illustrated in a tenth exemplary structure shown in FIGS. 28A-28D.

In such cases, the pattern of the retro-stepped dielectric material portions (165, 265, 365) with the fourth multi-tier structure M4 may be a mirror image pattern of the pattern of the retro-stepped dielectric material portions (165, 265, 365) with the first multi-tier structure M1; the pattern of the retro-stepped dielectric material portions (165, 265, 365) with the fifth multi-tier structure M5 may be a mirror image pattern of the pattern of the retro-stepped dielectric material portions (165, 265, 365) with the second multi-tier structure M2; and the pattern of the retro-stepped dielectric material portions (165, 265, 365) with the sixth multi-tier structure M6 may be a mirror image pattern of the pattern of the retro-stepped dielectric material portions (165, 265, 365) with the third multi-tier structure M3. The plane of the mirror symmetry for the pair of the fourth multi-tier structure M4 and the first multi-tier structure M1 may be located within a first-type lateral isolation trench fill structure 761 located between the fourth multi-tier structure M4 and the first multi-tier structure M1. The plane of the mirror symmetry for the pair of the fifth multi-tier structure M5 and the second multi-tier structure M2 may be located within a first-type lateral isolation trench fill structure 761 located between the fifth multi-tier structure M5 and the second multi-tier structure M2. The plane of the mirror symmetry for the pair of the sixth multi-tier structure M6 and the third multi-tier structure M3 may be located within a first-type lateral isolation trench fill structure 761 located between the sixth multi-tier structure M6 and the third multi-tier structure M3.

According to an aspect of the present disclosure, the pattern of the retro-stepped dielectric material portions (165, 265, 365) within different multi-tier structures MS within a repetition unit RU may differ from each other by differences other than a mirror symmetry. For example, the pattern of the retro-stepped dielectric material portions (165, 265, 365) within a second multi-tier structure M2 may be different from the pattern of the retro-stepped dielectric material portions (165, 265, 365) within a first multi-tier structure M1; the pattern of the retro-stepped dielectric material portions (165, 265, 365) within a third multi-tier structure M3 may be different from the pattern of the retro-stepped dielectric material portions (165, 265, 365) within the first multi-tier structure M1; and the pattern of the retro-stepped dielectric material portions (165, 265, 365) within the third multi-tier structure M3 may be different from the pattern of the retro-stepped dielectric material portions (165, 265, 365) within the second multi-tier structure M2.

Accordingly, the relative magnitudes among the first lateral extent LE1, the second lateral extent LE2, and the third lateral extent LE3 within the second multi-tier structure M2 may be different from the relative magnitudes among the first lateral extent LE1, the second lateral extent LE2, and the third lateral extent LE3 within the first multi-tier structure M1; the relative magnitudes among the first lateral extent LE1, the second lateral extent LE2, and the third lateral extent LE3 within the third multi-tier structure M3 may be different from the relative magnitudes among the first lateral extent LE1, the second lateral extent LE2, and the third lateral extent LE3 within the first multi-tier structure M1; and the relative magnitudes among the first lateral extent LE1, the second lateral extent LE2, and the third lateral extent LE3 within the third multi-tier structure M3 may be different from the relative magnitudes among the first lateral extent LE1, the second lateral extent LE2, and the third lateral extent LE3 within the second multi-tier structure M1.

Referring collectively to FIGS. 27A-28D and all related drawings and according to various embodiments of the present disclosure, a device structure comprises a plurality of multi-tier structures MS laterally spaced apart from each other along the second horizontal direction hd2 by a plurality of lateral isolation trenches 79 that laterally extend along a first horizontal direction hd1 which is perpendicular to the second horizontal direction hd1. Each multi-tier structure MS within the plurality of multi-tier structures MS comprises a first-tier structure (132, 146, 165) including a first-tier alternating stack (132, 146) of first-tier insulating layers 132 and first-tier electrically conductive layers 146, a second-tier structure (232, 246, 265) overlying the first-tier structure (132, 146, 165) and including a second-tier alternating stack (232, 246) of second-tier insulating layers 232 and second-tier electrically conductive layers 246, and a third-tier structure (332, 346, 365) overlying the second-tier structure (232, 246, 265) and including a third-tier alternating stack (332, 346) of third-tier insulating layers 332 and third-tier electrically conductive layers 346. Each of the multi-tier structures MS embeds a respective set of retro-stepped dielectric material portions (165, 265, 365), wherein the first-tier alternating stack (132, 146) of each multi-tier structure MS embeds a first subset of the respective set of retro-stepped dielectric material portions (165, 265, 365), the second-tier alternating stack (232, 246) of each multi-tier structure MS embeds a second subset of the respective set of retro-stepped dielectric material portions (165, 265, 365), and the third-tier alternating stack (332, 346) of each multi-tier structure MS embeds a third subset of the respective set of retro-stepped dielectric material portions (165, 265, 365). Within each multi-tier structure MS, the first subset 165 has a first lateral extent LE1 which is a maximum lateral spacing along the first horizontal direction hd1 among sidewalls of the first subset 165 that are perpendicular to the first horizontal direction hd1, the second subset 265 has a second lateral extent LE2 which is a maximum lateral spacing along the first horizontal direction hd1 among sidewalls of the second subset 265 that are perpendicular to the first horizontal direction hd1, and the third subset 365 has a third lateral extent LE3 which is a maximum lateral spacing along the first horizontal direction hd1 among sidewalls of the third subset 365 that are perpendicular to the first horizontal direction hd1. The plurality of multi-tier structures MS comprises a first multi-tier structure M1 and a second multi-tier structure M2. The second lateral extent LE2 of the first multi-tier structure M1 is less than the first lateral extent LE1 of the first multi-tier structure M1. The second lateral extent LE2 of the second multi-tier structure M2 is greater than the first lateral extent LE1 of the second multi-tier structure M2.

In one embodiment, the third lateral extent LE3 of the first multi-tier structure M1 is less than the second lateral extent LE2 of the first multi-tier structure M1; and the third lateral extent LE3 of the second multi-tier structure M2 is less than the second lateral extent LE2 of the second multi-tier structure M2.

In one embodiment, the third lateral extent LE3 of the first multi-tier structure M1 is less than the first lateral extent LE1 of the first multi-tier structure M1; and the third lateral extent LE3 of the second multi-tier structure M2 is greater than the first lateral extent LE1 of the second multi-tier structure M2.

In one embodiment, the plurality of multi-tier structures MS comprises a third multi-tier structure M3; and the second lateral extent LE2 of the third multi-tier structure M3 is less than the first lateral extent LE1 of the third multi-tier structure M3 and is less than the second lateral extent LE2 of the first multi-tier structure M1. In one embodiment, the third lateral extent LE3 of the third multi-tier structure M3 is greater than the first lateral extent LE1 of the third multi-tier structure M3, is greater than the third lateral extent LE3 of the first multi-tier structure M1, and is greater than the third lateral extent LE3 of the second multi-tier structure M2.

In one embodiment, within each multi-tier structure MS, each subset among the first subset, the second subset, and the third subset of the retro-stepped dielectric material portions comprises three or more retro-stepped dielectric material portions (165, 265, or 365) that are laterally spaced apart from each other along the first horizontal direction hd1. In one embodiment, each of the multi-tier structures MS comprises a respective set of through-via contact structures 86 vertically extending between a horizontal plane including a top surface of a topmost layer of the third-tier alternating stack (332, 346) and a horizontal plane including a bottom surface of a bottommost layer of the first-tier alternating stack (132, 146) and electrically connected to a single electrically conductive layer 46 among the first-tier electrically conductive layers 146, the second-tier electrically conductive layers 246, and the third-tier electrically conductive layers 346.

The various embodiments of the present disclosure provide various patterns for the retro-stepped dielectric material portion (165, 265, 365) and underlying staircase regions, which may be employed to facilitate planarization of the dielectric materials of the retro-stepped dielectric material portion (165, 265, 365) during manufacturing steps, by forming smaller area retro-stepped dielectric material portions (165, 265, 365) distributed over wider area of the contact region 200. This reduces dishing of the dielectric material during the CMP planarization thereof to form the retro-stepped dielectric material portions.

In the embodiments of FIGS. 1-24, the retro-stepped dielectric material portions (165, 265, 365) and underlying staircase regions are laterally separated into plural areas in each tier in a given contact region 200 between two adjacent memory array regions 200. In the embodiments of FIGS. 25 and 26, the alternating stack (32, 46) layers of an overlying tier overlies the retro-stepped dielectric material portion of an underlying tier to avoid having two retro-stepped dielectric material portions of two vertically adjacent tiers directly overlie each other. In the embodiments of FIGS. 27A-27D and 28A-28D, neighboring retro-stepped dielectric material portions along the second horizontal direction (e.g., bit line direction) hd2 are laterally offset from each other along the first horizontal direction (e.g., word line direction) hd1 to reduce dishing during CMP by reducing the amount of closely spaced retro-stepped dielectric material portions in each tier.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A device structure, comprising:
a multi-tier structure comprising a first-tier structure including a first-tier alternating stack of first-tier insulating layers and first-tier electrically conductive layers, a second-tier structure overlying the first-tier structure and including a second-tier alternating stack of second-tier insulating layers and second-tier electrically conductive layers, and a third-tier structure overlying the second-tier structure and including a third-tier alternating stack of third-tier insulating layers and third-tier electrically conductive layers;
a first memory array region comprising a plurality of first memory opening fill structures vertically extending through the multi-tier structure;
a second memory array region comprising a plurality of second memory opening fill structures vertically extending through the multi-tier structure, the second memory array region is laterally offset from the first memory array region along a first horizontal direction by a contact region of the multi-tier structure; and
a set of retro-stepped dielectric material portions embedded in the contact region,
wherein:
the first-tier alternating stack embeds a first subset of the respective set of retro-stepped dielectric material portions, the second-tier alternating stack embeds a second subset of the respective set of retro-stepped dielectric material portions, and the third-tier alternating stack embeds a third subset of the respective set of retro-stepped dielectric material portions; and
at least one subset of the first subset, the second subset, or the third subset comprises three or more retro-stepped dielectric material portions that are laterally spaced apart from each other along the first horizontal direction.

2. The device structure of claim 1, further comprising:
staircase regions underlying the set of retro-stepped dielectric material portions; and
a plurality of through-via contact structures vertically extending between a horizontal plane including a top surface of a topmost layer of the third-tier alternating stack and a horizontal plane including a bottom surface of a bottommost layer of the first-tier alternating stack and electrically connected to a single electrically conductive layer of the first-tier electrically conductive layers, the second-tier electrically conductive layers, and the third-tier electrically conductive layers in a respective one of the staircase regions.

3. The device structure of claim 2, wherein the plurality of the through-via contact structures comprises:
first through-via contact structures vertically extending through each of the second-tier electrically conductive layers and the third-tier electrically conductive layers and electrically connected to a respective one of the first-tier electrically conductive layers;
second through-via contact structures vertically extending through each of the first-tier electrically conductive layers and the third-tier electrically conductive layers and electrically connected to a respective one of the second-tier electrically conductive layers; and
third through-via contact structures vertically extending through each of the first-tier electrically conductive layers and the second-tier electrically conductive layers and electrically connected to a respective one of the third-tier electrically conductive layers.

4. The device structure of claim 3, wherein:
each of the first through-via contact structures is electrically isolated from each of the second-tier electrically conductive layers and the third-tier electrically conductive layers by annular dielectric spacers that are located within openings through the second-tier electrically conductive layers and the third-tier electrically conductive layers;
each of the second through-via contact structures is electrically isolated from each of the first-tier electrically conductive layers and the third-tier electrically conductive layers by annular dielectric spacers that are located within openings through the first-tier electrically conductive layers and the third-tier electrically conductive layers; and
each of the third through-via contact structures is electrically isolated from each of the first-tier electrically conductive layers and the second-tier electrically conductive layers by annular dielectric spacers that are located within openings through the first-tier electrically conductive layers and the second-tier electrically conductive layers.

5. The device structure of claim 2, wherein each of the plural through-via contact structures vertically extends through no more than one retro-stepped dielectric material portion within the set of retro-stepped dielectric material portions.

6. The device structure of claim 1, wherein:
each of the first memory opening fill structures comprises a respective first semiconductor channel and a respective first memory film; and
each of the second memory opening fill structures comprises a respective second semiconductor channel and a respective second memory film.

7. The device structure of claim 1, wherein:
each of the first-tier, second-tier and third-tier electrically conductive layers continuously extends from the first memory array region to the second memory array region through a bridge portion of the contact region; and
the bridge portion of the contact region is laterally offset from the set of retro-stepped dielectric material portions along a second horizontal direction which is perpendicular to the first horizontal direction.

8. The device structure of claim 1, wherein each of the retro-stepped dielectric material portions within the respective set of retro-stepped dielectric material portions overlies least one ascending staircase portion and at least one descending staircase portion.

9. The device structure of claim 1, wherein at least two subsets of the first subset, the second subset, and the third subset comprises three or more retro-stepped dielectric material portions that are laterally spaced apart from each other along the first horizontal direction.

10. The device structure of claim 1, wherein each subset of the first subset, the second subset, and the third subset comprises three or more retro-stepped dielectric material portions that are laterally spaced apart from each other along the first horizontal direction.

11. The device structure of claim 1, wherein the at least one subset of the first subset, the second subset, and the third subset comprises four retro-stepped dielectric material portions that are laterally spaced apart from each other along the first horizontal direction.

12. The device structure of claim 1, further comprising:
a second multi-tier structure which is laterally spaced from the multi-tier structure along a second horizontal direction which is perpendicular to the first horizontal direction by a lateral isolation trench which extends in the first horizontal direction; and
a lateral isolation trench fill structure located in the lateral isolation trenches,.

13. A device structure compries a plurality of multi-tier structures that are laterally spaced apart from each other along a second horizontal direction by a plurality of lateral isolation trenches that laterally extend along a first horizontal direction which is perpendicular to the second horizontal direction, wherein:
each multi-tier structure within the plurality of multi-tier structures comprises a first-tier structure including a first-tier alternating stack of first-tier insulating layers and first-tier electrically conductive layers, a second-tier structure overlying the first-tier structure and including a second-tier alternating stack of second-tier insulating layers and second-tier electrically conductive layers, and a third-tier structure overlying the second-tier structure and including a third-tier alternating stack of third-tier insulating layers and third-tier electrically conductive layers;
each of the multi-tier structures embeds a respective set of retro-stepped dielectric material portions, wherein the first-tier alternating stack of each multi-tier structure embeds a first subset of the respective set of retro-stepped dielectric material portions, the second-tier alternating stack of each multi-tier structure embeds a second subset of the respective set of retro-stepped dielectric material portions, and the third-tier alternating stack of each multi-tier structure embeds a third subset of the respective set of retro-stepped dielectric material portions;
within each multi-tier structure, the first subset has a first lateral extent along the first horizontal direction, the second subset has a second lateral along the first horizontal direction, and the third subset has a third lateral extent along the first horizontal direction;
the plurality of multi-tier structures comprises a first multi-tier structure and a second multi-tier structure;
the second lateral extent of the first multi-tier structure is less than the first lateral extent of the first multi-tier structure; and
the second lateral extent of the second multi-tier structure is greater than the first lateral extent of the second multi-tier structure.

14. The device structure of claim 13, wherein:
the third lateral extent of the first multi-tier structure is less than the second lateral extent of the first multi-tier structure; and
the third lateral extent of the second multi-tier structure is less than the second lateral extent of the second multi-tier structure.

15. The device structure of claim 14, wherein:
the third lateral extent of the first multi-tier structure is less than the first lateral extent of the first multi-tier structure; and
the third lateral extent of the second multi-tier structure is greater than the first lateral extent of the second multi-tier structure.

16. The device structure of claim 14, wherein:
the plurality of multi-tier structures further comprises a third multi-tier structure; and
the second lateral extent of the third multi-tier structure is less than the first lateral extent of the third multi-tier structure and is less than the second lateral extent of the first multi-tier structure.

17. The device structure of claim 16, wherein the third lateral extent of the third multi-tier structure is greater than the first lateral extent of the third multi-tier structure, is greater than the third lateral extent of the first multi-tier structure, and is greater than the third lateral extent of the second multi-tier structure.

18. The device structure of claim 13, wherein within each of the multi-tier structures, each subset of the first subset, the second subset, and the third subset comprises three or more retro-stepped dielectric material portions that are laterally spaced apart from each other along the first horizontal direction.

19. The device structure of claim 13, wherein each of multi-tier structures comprises a respective set of through-via contact structures vertically extending between a horizontal plane including a top surface of a topmost layer of the third-tier alternating stack and a horizontal plane including a bottom surface of a bottommost layer of the first-tier alternating stack and electrically connected to a single electrically conductive layer of the first-tier electrically conductive layers, the second-tier electrically conductive layers, and the third-tier electrically conductive layers.

20. The device structure of claim 19, wherein each of multi-tier structures further comprises:
a first memory array region comprising a plurality of first memory opening fill structures vertically extending through the multi-tier structure; and
a second memory array region comprising a plurality of second memory opening fill structures vertically extending through the multi-tier structure, the second memory array region is laterally offset from the first memory array region along the first horizontal direction by a contact region of the multi-tier structure,
wherein:
the set of retro-stepped dielectric material portions is embedded in the contact region;
each of the first-tier, second-tier and third-tier electrically conductive layers continuously extends from the first memory array region to the second memory array region through a bridge portion of the contact region; and
the bridge portion of the contact region is laterally offset from the set of retro-stepped dielectric material portions along the second horizontal direction.
